(19) United States
(12) Patent Application Publication
(10) Pub. No.: US 2022/0180615 A1
(43) Pub. Date: Jun. 9, 2022

(54) IMAGING SYSTEM AND IMAGING DEVICE

(71) Applicant: SONY GROUP CORPORATION, TOKYO (JP)

(72) Inventors: YOSHITAKA MIYATANI, TOKYO (JP); SHINNOSUKE HAYAMIZU, KANAGAWA (JP); KAZUYUKI MARUKAWA, TOKYO (JP); MIHO KOMAI, TOKYO (JP)

(21) Appl. No.: 17/594,467

(22) PCT Filed: Apr. 14, 2020
(86) PCT No.: PCT/JP2020/016360

§ 371 Date: Oct. 18, 2021

(30) Foreign Application Priority Data
Apr. 26, 2019 (JP) 2019-085074

(51) Int. Cl. G06V 10/147; G06V 20/58; H04N 7/18; H04N 5/225; H04N 5/232; H01L 27/146; B60R 11/04

(52) U.S. Cl. CPC G06V 10/147; G06V 20/58; H04N 7/18; H04N 5/2253; H04N 5/23229; H01L 27/14607; B60R 2011/0026; H01L 27/14623; H01L 27/14627; H01L 27/1463; H01L 27/14634; H01L 27/14645; B60R 11/04; H01L 27/14621

(57) ABSTRACT

The present technology relates to an imaging system and an imaging device that enable imaging at an appropriate angle of view while preventing reflection, in a case where imaging of the surroundings of a vehicle is performed from inside the vehicle. An imaging system includes an imaging device that includes a plurality of pixels that receives incident light entering from an object after passing through neither an imaging lens nor a pinhole and each outputs a detection signal indicating an output pixel value modulated in accordance with the incident angle of the incident light, the imaging device being mounted so that the light receiving surface faces the surface of a windshield on the inner side of a vehicle and is in contact with or in proximity to the surface of the windshield. In this imaging system, the average of the centroids of incident angle directivities indicating the directivities of the plurality of pixels with respect to the incident angle of the incident light is biased in one direction from the center of the pixel. The present technology can be applied to an in-vehicle system, for example.

### TECHNICAL FIELD

The present technology relates to imaging systems and imaging devices, and more particularly, to an imaging system and an imaging device that are suitable for use in a case where the surroundings of a vehicle are imaged from inside the vehicle.

### BACKGROUND ART

There has been a conventional camera device that is attached to the windshield of a vehicle from inside the vehicle, to capture an image of the view in front of the vehicle (see Patent Document 1, for example).

### CITATION LIST

### Patent Document

Patent Document 1: Japanese Patent Application Laid-Open No. 2016-203952

### SUMMARY OF THE INVENTION

### Problems to be Solved by the Invention

However, in the camera device disclosed in Patent Document 1, a space is formed between the lens of the camera module provided in the camera device and the windshield, and therefore, there is a possibility that incident light will be reflected, resulting in reflection in the windshield. On the other hand, when the lens of the camera module is brought close to the windshield so as to prevent reflection, the imaging direction shifts upward, and the view in front of the vehicle cannot be imaged at an appropriate angle of view.

The present technology has been made in view of such circumstances, and is to enable imaging at an appropriate angle of view while preventing reflection in a case where imaging of the surroundings of a vehicle is performed from inside the vehicle.

### Solutions to Problems

An imaging system of a first aspect of the present technology includes an imaging device that includes a plurality of pixels that receives incident light entering from an object after passing through neither an imaging lens nor a pinhole and each outputs a detection signal indicating an output pixel value modulated in accordance with the incident angle of the incident light, the imaging device being mounted so that the light receiving surface faces the surface of a windshield on the inner side of a vehicle and is in contact with or in proximity to the surface of the windshield. In this imaging system, the average of the centroids of incident angle directivities indicating the directivities of the plurality of pixels with respect to the incident angle of the incident light is biased in one direction from the center of the pixel.

An imaging device of a second aspect of the present technology includes a plurality of pixels that receives incident light entering from an object after passing through neither an imaging lens nor a pinhole, and each outputs a detection signal indicating an output pixel value modulated in accordance with the incident angle of the incident light. In the imaging device, the average of the centroids of incident angle directivities indicating the directivities of the plurality of pixels with respect to the incident angle of the incident light deviates from the center of the pixel.

In the first aspect of the present technology, imaging is performed in a direction deviating from the front direction of a vehicle.

In the second aspect of the present technology, imaging is performed in a direction deviating from the front direction.

### BRIEF DESCRIPTION OF DRAWINGS

FIG. 1 is a block diagram showing an example configuration of an in-vehicle system according to the present technology.

FIG. 2 is a block diagram showing an example configuration of the imaging unit of the in-vehicle system shown in FIG. 1.

FIG. 3 is a diagram for explaining the principles of imaging in the imaging device shown in FIG. 2.

FIG. 4 is a diagram showing an example configuration of the pixel array unit of the imaging device shown in FIG. 2.

FIG. 5 is a diagram for explaining a first example configuration of the imaging device shown in FIG. 2.

FIG. 6 is a diagram for explaining a second example configuration of the imaging device shown in FIG. 2.

FIG. 7 is a diagram for explaining the principles of generation of incident angle directivities.

FIG. 8 is a diagram for explaining changes in incident angle directivity using on-chip lenses.

FIG. 9 is a diagram for explaining the relationship between a narrow angle-of-view pixel and a wide angle-of-view pixel.

FIG. 10 is a diagram for explaining the relationship between a narrow angle-of-view pixel and a wide angle-of-view pixel.

FIG. 11 is a diagram for explaining the relationship between a narrow angle-of-view pixel and a wide angle-of-view pixel.

FIG. 12 is a diagram for explaining a difference in image quality between a narrow angle-of-view pixel and a wide angle-of-view pixel.

FIG. 13 is a diagram for explaining a difference in image quality between a narrow angle-of-view pixel and a wide angle-of-view pixel.

FIG. 14 is a diagram for explaining an example combination of pixels having a plurality of angles of view.

FIG. 15 is a diagram showing an example hardware configuration of the front camera module shown in FIG. 1.

FIG. 16 is a diagram showing an example method for attaching the front camera module shown in FIG. 1.

FIG. 17 is a diagram showing an example method for attaching the front camera module shown in FIG. 1.

FIG. 18 is a diagram showing a first embodiment of the pixel array unit of the imaging device shown in FIG. 2.

FIG. 19 is a diagram showing an example of the light shielding pattern of the pixels shown in FIG. 18.

FIG. 20 is a diagram showing the imaging range of the imaging device shown in FIG. 18.

FIG. 21 is a flowchart for explaining an imaging process to be performed by the imaging unit shown in FIG. 2.

FIG. 22 is a diagram showing a second embodiment of the pixel array unit of the imaging device shown in FIG. 2.

FIG. 23 is a diagram showing an example of the light shielding pattern of the pixels shown in FIG. 22.

FIG. 24 is a diagram showing the imaging range of the imaging device shown in FIG. 22.

FIG. 25 is a diagram showing a third embodiment of the pixel array unit of the imaging device shown in FIG. 2.

FIG. 26 is a diagram showing an example of the light shielding pattern of the pixels shown in FIG. 25.

FIG. 27 is a diagram showing the imaging range of the imaging device shown in FIG. 25.

FIG. 28 is a diagram showing a modification of the method for installing the front camera module.

FIG. 29 is a diagram for explaining a third example configuration of the imaging device shown in FIG. 2.

FIG. 30 is a diagram showing a modification of the imaging device.

FIG. 31 is a diagram showing a modification of the imaging device.

FIG. 32 is a diagram showing a modification of the imaging device.

FIG. 33 is a diagram showing a modification of the imaging device.

FIG. 34 is a diagram showing a modification of the imaging device.

### MODES FOR CARRYING OUT THE INVENTION

The following is a detailed description of preferred embodiments of the present technology, with reference to the accompanying drawings. Note that, in this specification and the drawings, components having substantially the same functional configurations are denoted by the same reference numerals, and repeated explanation of them will not be made.

Further, explanation will be made in the following order.

1. First embodiment

2. Second embodiment

3. Third embodiment

4. Modifications

5. Other aspects

### 1. First Embodiment

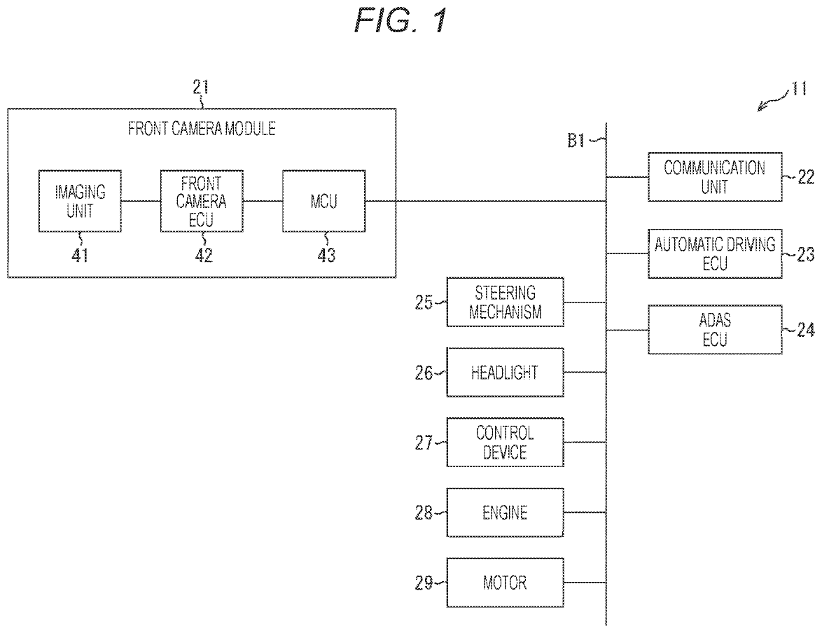

Referring to FIGS. 1 to 21, a first embodiment of the present technology is first described.

<Example Configuration of an In-Vehicle System 11>

FIG. 1 is a block diagram showing an example configuration of an in-vehicle system 11 according to the present technology.

The in-vehicle system 11 is a system that is provided in a vehicle, and performs control and the like on the vehicle.

The in-vehicle system 11 includes a front camera module 21, a communication unit 22, an automatic driving electronic control unit (ECU) 23, an advanced driver assistance system (ADAS) ECU 24, a steering mechanism 25, a headlight 26, a braking device 27, an engine 28, and a motor 29. The front camera module 21, the communication unit 22, the automatic driving ECU 23, the ADAS ECU 24, the steering mechanism 25, the headlight 26, the braking device 27, the engine 28, and the motor 29 are connected to one another via a bus B1 designed for controller area network (CAN) communication.

Note that, in the description below, the bus B1 in a case where each component of the in-vehicle system 11 performs data transmission/reception or the like via the bus B1 will not be mentioned, for ease of explanation. For example, a case where the ADAS ECU 24 supplies data to the steering mechanism 25 via the bus B1 will be described as a case where the ADAS ECU 24 supplies data to the steering mechanism 25.

The front camera module 21 is installed on the vehicle's interior side of the windshield of the vehicle, performs processing such as imaging and image recognition of the view in front of the vehicle, and supplies data indicating a result of the processing to each component of the in-vehicle system 11, as will be described later. The front camera module 21 includes an imaging unit 41, a front camera ECU 42, and a micro control unit (MCU) 43.

The imaging unit 41 includes a lens-less camera (LLC) that uses neither an imaging lens nor a pinhole, as will be described later. The imaging unit 41 restores, from a detection image obtained by imaging, a restored image in which an image of an object is formed, and supplies the restored image as a sensing image obtained by sensing the view in front of the vehicle, to the front camera ECU 42, as will be described later.

The front camera ECU 42 performs an image quality adjustment process such as gain adjustment, white balance adjustment, a high dynamic range (HDR) process, and a traffic-signal flicker correction process on the sensing image supplied from the imaging unit 41, and then performs image recognition on the sensing image, for example. Note that the image quality adjustment process is not necessarily performed by the front camera ECU 42, but may be performed inside the imaging unit 41.

During the image recognition, objects such as a pedestrian, a light road vehicle such as a bicycle, a vehicle, a headlight, a brake lamp, a sidewalk, a guardrail, a traffic light, a road marking such as a lane marking, and a road sign are detected, and the time till a collision with a vehicle running ahead and the like are detected, for example. The front camera ECU 42 generates a signal indicating the result of the detection by the image recognition, and supplies the signal to the automatic driving ECU 23 via the MCU 43.

The front camera ECU 42 also generates a control signal for assisting various kinds of driving on the basis of the result of the detection by the image recognition performed on the sensing image, and supplies the control signal to the ADAS ECU 24 via the MCU 43. For example, the front camera ECU 42 generates a control signal for issuing an instruction for a change in the traveling direction, deceleration, sudden braking, warning notification, or the like to avoid danger such as a collision with an object or deviation from a traveling lane (driving lane), on the basis of the result of detection of a lane marking, a curbstone, a pedestrian, or the like on a road obtained by the image recognition. The front camera ECU 42 then supplies the control signal to the ADAS ECU 24 via the MCU 43. The front camera ECU 42 also generates a control signal for issuing an instruction for switching between a low beam and a high beam or the like on the basis of the presence/absence of the headlight of an oncoming vehicle obtained by the image recognition, for example, and supplies the control signal to the ADAS ECU 24 via the MCU 43.

The MCU 43 converts the signal supplied from front camera ECU 42 into a signal in a format for CAN communication, and outputs the signal to the bus B1. The MCU 43 also converts a signal received from the bus B1 into a signal in a format for the front camera ECU 42, and supplies the signal to the front camera ECU 42.

The communication unit 22 transmits/receives information to and from a surrounding vehicle, a portable terminal device being carried by a pedestrian, a roadside device, and an external server by various kinds of wireless communication such as vehicle-to-vehicle communication, vehicle-to-pedestrian communication, and road-to-vehicle communication. For example, the communication unit 22 performs vehicle-to-vehicle communication with a surrounding vehicle, receives surrounding vehicle information including information indicating the number of occupants and a traveling status from the surrounding vehicle, and supplies the surrounding vehicle information to the automatic driving ECU 23.

The automatic driving ECU 23 is an ECU to be used for executing an automatic driving (self driving) function of the vehicle. For example, the automatic driving ECU 23 controls automatic driving of the vehicle on the basis of various kinds of information such as a result of object detection performed by the front camera ECU 42, positional information about the vehicle, and surrounding vehicle information supplied from the communication unit 22, sensor data from various sensors provided in the vehicle, a result of detection of a vehicle speed, and the like. For example, the automatic driving ECU 23 controls the steering mechanism 25, the headlight 26, the braking device 27, the engine 28, the motor 29, and the like, to perform driving control such as changing the traveling direction, braking, accelerating, and starting, warning notification control, beam switching control, and the like.

The ADAS ECU 24 is an ECU to be used for executing an advanced driving assistant system (ADAS) function of the vehicle. The ADAS ECU 24 controls the steering mechanism 25, the headlight 26, the braking device 27, the engine 28, the motor 29, and the like on the basis of a control signal from the front camera ECU 42, for example, to control various kinds of driving assistance.

The steering mechanism 25 operates in accordance with an operation of the steering wheel by the driver or a control signal supplied from the automatic driving ECU 23 or the ADAS ECU 24, and performs control on the traveling direction of the vehicle, or performs steering angle control.

The headlight 26 operates in accordance with a control signal supplied from the automatic driving ECU 23 or the ADAS ECU 24, and illuminates the area in front of the vehicle by emitting a beam.

The braking device 27 operates in accordance with a brake operation by the driver or a control signal supplied from the automatic driving ECU 23 or the ADAS ECU 24, and stops or decelerates the vehicle.

The engine 28 is a power source of the vehicle, and is driven in accordance with a control signal supplied from the automatic driving ECU 23 or the ADAS ECU 24.

The motor 29 is a power source of the vehicle, receives power supply from a generator or a battery (not shown), and is driven in accordance with a control signal from the automatic driving ECU 23 or the ADAS ECU 24.

Note that driving the engine 28 and driving the motor 29 are switched by the automatic driving ECU 23, as appropriate, during running of the vehicle.

<Example Configuration of the Imaging Unit 41>

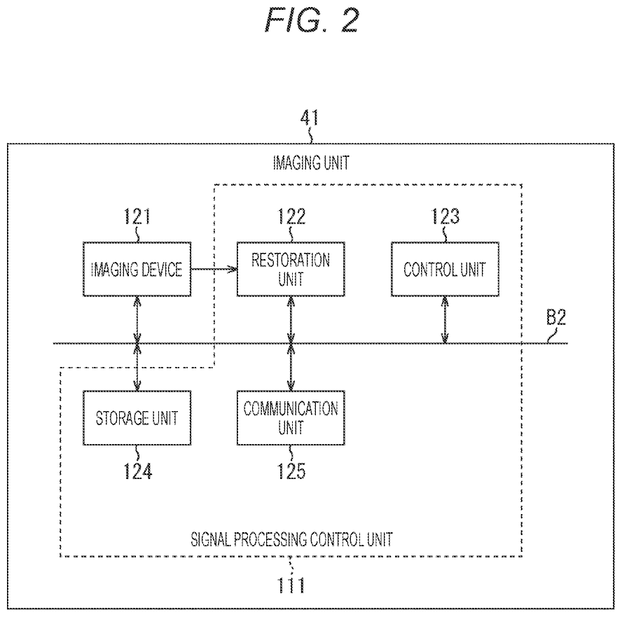

FIG. 2 is a block diagram showing an example configuration of the imaging unit 41 of the front camera module 21.

The imaging unit 41 includes an imaging device 121, a restoration unit 122, a control unit 123, a storage unit 124, and a communication unit 125. Further, the restoration unit 122, the control unit 123, the storage unit 124, and the communication unit 125 constitute a signal processing control unit 111 that performs signal processing, control on the imaging unit 41, and the like. Note that the imaging unit 41 does not include any imaging lens (free of imaging lenses).

Further, the imaging device 121, the restoration unit 122, the control unit 123, the storage unit 124, and the communication unit 125 are connected to one another via a bus B2, and transmit/receive data and the like via the bus B2. Note that, in the description below, the bus B2 in a case where each component of the imaging unit 41 performs data transmission/reception or the like via the bus B2 will not be mentioned, for ease of explanation. For example, a case where the communication unit 125 supplies data to the control unit 123 via the bus B2 will be described as a case where the communication unit 125 supplies data to the control unit 123.

The imaging device 121 is an imaging device in which the detection sensitivity of each pixel has an incident angle directivity, and outputs an image including a detection signal indicating a detection signal level corresponding to the amount of incident light, to the restoration unit 122 or the bus B2. The detection sensitivity of each pixel having an incident angle directivity means that the light-receiving sensitivity characteristics corresponding to the incident angle of incident light entering each pixel vary with each pixel. However, the light-receiving sensitivity characteristics of all the pixels are not necessarily completely different, and the light-receiving sensitivity characteristics of some pixels may be the same.

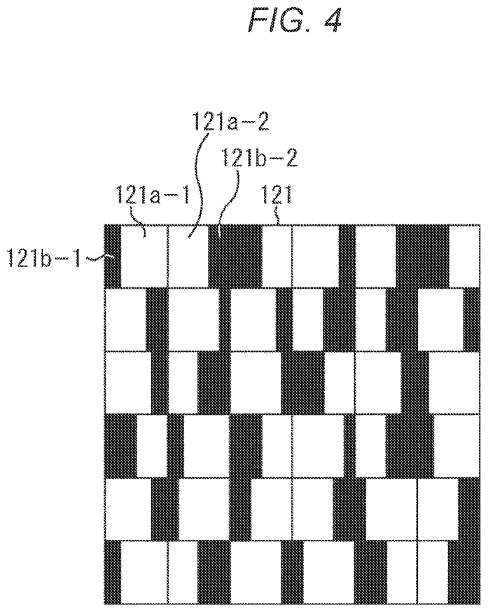

More specifically, the imaging device 121 may have a basic structure similar to that of a general imaging device such as a complementary metal oxide semiconductor (CMOS) image sensor, for example. However, the configuration of each of the pixels constituting the pixel array unit of the imaging device 121 differs from that of a general imaging device, and is a configuration that has an incident angle directivity, as will be described later with reference to FIGS. 4 to 6, for example. Further, the imaging device 121 has light-receiving sensitivity that varies (changes) with the incident angle of incident light in each pixel, and has an incident angle directivity with respect to the incident angle of incident light in each pixel.

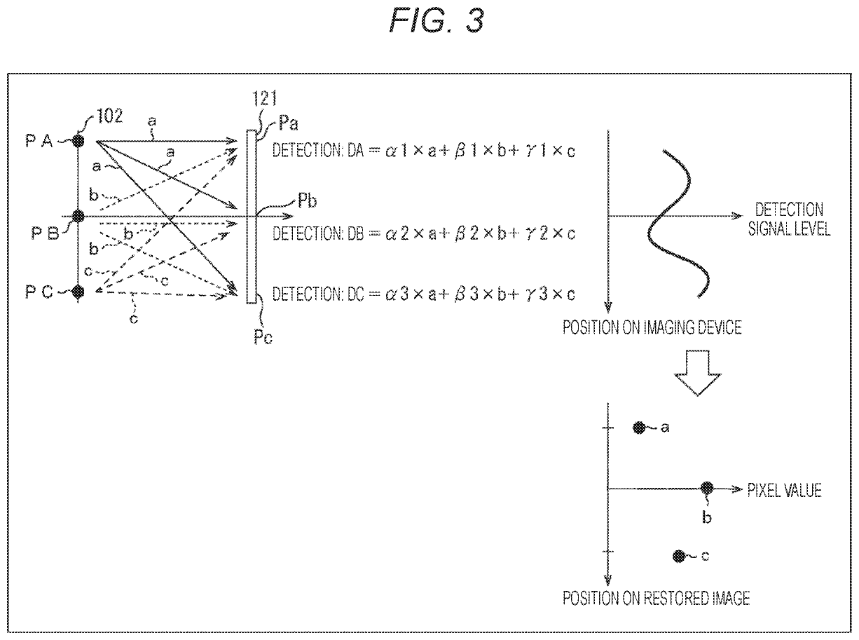

Here, all objects are a set of point light sources, for example, and light is emitted from each point light source in all directions. For example, an object surface 102 of an object in the top left of FIG. 3 is formed with point light sources PA to PC, and the point light sources PA to PC emit a plurality of light beams of light intensities a to c, respectively, to the surroundings. Further, in the description below, the imaging device 121 includes pixels (hereinafter referred to as pixels Pa to Pc) having different incident angle directivities at positions Pa to Pc.

In this case, as shown in the top left of FIG. 3, light beams of the same light intensity emitted from the same point light source are made to enter the respective pixels of the imaging device 121. For example, a light beam of the light intensity a emitted from the point light source PA is made to enter the respective pixels Pa to Pc of the imaging device 121. However, light beams emitted from the same point light source are made to enter the respective pixels at different incident angles. For example, light beams from the point light source PA are made to enter the respective pixels Pa to Pc at different incident angles.

On the other hand, since the incident angle directivities of the pixels Pa to Pc differ from one another, light beams of the same light intensity emitted from the same point light source are detected with different sensitivities in the respective pixels. As a result, light beams of the same light intensity are detected at different detection signal levels in the respective pixels. For example, the detection signal levels with respect to the light beams of the light intensity a from the point light source PA have different values in the respective pixels Pa to Pc.

Further, the light-receiving sensitivity level of each pixel with respect to a light beam from each point light source is determined by multiplying the light intensity of the light beam by a coefficient indicating the light-receiving sensitivity (which is the incident angle directivity) with respect to the incident angle of the light beam. For example, the detection signal level of the pixel Pa with respect to the light beam from the point light source PA is determined by multiplying the light intensity a of the light beam of the point light source PA by a coefficient indicating the incident angle directivity of the pixel Pa with respect to the incident angle of the light beam entering the pixel Pa.

Accordingly, the detection signal levels DA, DB, and DC of the pixels Pc, Pb, and Pa are expressed by Equations (1) to (3) shown below, respectively.

DA=α1×a+β1×b+γ1×c (1)

DB=α2×a+β2×b+γ2×c (2)

DC=α3×a+β3×b+γ3×c (3)

Here, the coefficient α1 is a coefficient indicating the incident angle directivity of the pixel Pc with respect to the incident angle of the light beam from the point light source PA to the pixel Pc, and is set in accordance with the incident angle. Further, α1×a indicates the detection signal level of the pixel Pc with respect to the light beam from the point light source PA.

The coefficient 131 is a coefficient indicating the incident angle directivity of the pixel Pc with respect to the incident angle of the light beam from the point light source PB to the pixel Pc, and is set in accordance with the incident angle. Further, β1×b indicates the detection signal level of the pixel Pc with respect to the light beam from the point light source PB.

The coefficient γ1 is a coefficient indicating the incident angle directivity of the pixel Pc with respect to the incident angle of the light beam from the point light source PC to the pixel Pc, and is set in accordance with the incident angle. Further, γ1×c indicates the detection signal level of the pixel Pc with respect to the light beam from the point light source PC.

As described above, the detection signal level DA of the pixel Pa is determined by the sum of products of the respective light intensities a, b, and c of the light beams from the point light sources PA, PB, and PC in the pixel Pc, and the coefficients α1, β1, and γ1 indicating the incident angle directivities depending on the respective incident angles.

Likewise, the detection signal level DB of the pixel Pb is determined by the sum of products of the respective light intensities a, b, and c of the light beams from the point light sources PA, PB, and PC in the pixel Pb, and the coefficients α2, β2, and γ2 indicating the incident angle directivities depending on the respective incident angles, as shown in Equation (2). Also, the detection signal level DC of the pixel Pc is determined by the sum of products of the respective light intensities a, b, and c of the light beams from the point light sources PA, PB, and PC in the pixel Pa, and the coefficients α2, β2, and γ2 indicating the incident angle directivities depending on the respective incident angles, as shown in Equation (3).

However, the detection signal levels DA, DB, and DC of the pixels Pa, Pb, and Pc are mixed with the light intensities a, b, and c of the light beams emitted from the point light sources PA, PB, and PC, respectively, as shown in Equations (1) to (3). Therefore, as shown in the top right of FIG. 3, the detection signal level in the imaging device 121 differs from the light intensity of each point light source on the object surface 102. Accordingly, an image obtained by the imaging device 121 differs from that in which an image of the object surface 102 is formed.

Meanwhile, the light intensities a to c of the light beams of the respective point light sources PA to PC are determined by creating simultaneous equations formed with Equations (1) to (3) and solving the created simultaneous equations. The pixels having the pixel values corresponding to the obtained light intensities a to c are then arranged in accordance with the layout (relative positions) of the point light sources PA to PC, so that a restored image in which an image of the object surface 102 is formed is restored as shown in the bottom right of FIG. 3.

In this manner, the imaging device 121 that has an incident angle directivity in each pixel without requiring any imaging lens and any pinhole can be obtained.

In the description below, a set of coefficients (the coefficients α1, β1, and γ1, for example) for each of the equations forming the simultaneous equations will be referred to as a coefficient set. In the description below, a group formed with a plurality of coefficient sets (the coefficient set of α1, β1, and γ1, the coefficient set of α2, β2, and γ2, the coefficient set of α3, β3, and γ3, for example) corresponding to a plurality of equations included in the simultaneous equations will be referred to as a coefficient set group.

Here, if the object distance from the object surface 102 to the light receiving surface of the imaging device 121 varies, the incident angles of the light beams from the respective point light sources on the object surface 102 to the imaging device 121 vary, and therefore, a different coefficient set group is required for each object distance. Therefore, in the imaging unit 41, coefficient set groups for the respective distances (object distances) from the imaging device 121 to the object surface are prepared in advance, simultaneous equations are created by switching the coefficient set groups for each object distance, and the created simultaneous equations are solved. Thus, restored images of the object surface at various object distances can be obtained on the basis of one detection image. For example, after a detection image is captured and recorded once, the coefficient set groups are switched in accordance with the distance to the object surface, and a restored image is restored, so that a restored image of the object surface at a desired object distance can be generated.

Further, even on the object surface 102 at the same object distance, if the number and the layout of the point light sources to be set vary, the incident angles of the light beams from the respective point light sources to the imaging device 121 also vary. Therefore, a plurality of coefficient set groups might be required for the object surface 102 at the same object distance in some cases. Furthermore, the incident angle directivity of each pixel 121a needs to be set so that the independence of the simultaneous equations described above can be ensured.

Further, an image to be output by the imaging device 121 is an image formed with detection signals in which an image of the object is not formed as shown in the top right of FIG. 3, and therefore, the object cannot be visually recognized. That is, a detection image formed with detection signals output from the imaging device 121 is a set of pixel signals, but also is an image from which the user cannot visually recognize the object (the object is visually unrecognizable).

In view of this, an image formed with detection signals in which an image of the object is not formed as shown in the top right of FIG. 3, or an image captured by the imaging device 121, will be hereinafter referred to as a detection image.

Note that not all the pixels need to have different incident angle directivities from one another, but some pixels may have the same incident angle directivity.

The restoration unit 122 acquires, from the storage unit 124, a coefficient set group that corresponds to the object distance corresponding to the distance from the imaging device 121 to the object surface 102 (the object surface corresponding to the restored image) in FIG. 3, for example, and corresponds to the above coefficients α1 to α3, β1 to β3, and γ1 to γ3. The restoration unit 122 also creates simultaneous equations as expressed by Equations (1) to (3) described above, using the detection signal level of each pixel of the detection image output from the imaging device 121 and the acquired coefficient set group. The restoration unit 122 then solves the created simultaneous equations, to obtain the pixel values of the respective pixels constituting the image in which an image of the object as shown in the bottom right of FIG. 3 is formed. Thus, an image from which the user can visually recognize the object (visually recognizable object) is restored from the detection image.

The image restored from the detection image will be referred to as a restored image. However, in a case where the imaging device 121 has sensitivity only to light out of the visible wavelength band, such as ultraviolet rays, the restored image is not an image from which the object can be recognized as in a normal image, but is also referred to as a restored image in this case.

Further, a restored image that is an image in which an image of the object is formed and is an image not yet subjected to color separation such as demosaicing or a synchronization process will be hereinafter referred to as a RAW image, and a detection image captured by the imaging device 121 will be distinguished as an image compliant with the array of color filters, but not as a RAW image.

Note that the number of pixels of the imaging device 121 and the number of pixels constituting the restored image are not necessarily the same.

Further, the restoration unit 122 performs demosaicing, γ correction, white balance adjustment, conversion into a predetermined compression format, and the like, on the restored image as necessary. The restoration unit 122 then outputs the restored image to the bus B2.

The control unit 123 includes various processors, for example, to control each component of the imaging unit 41 and perform various kinds of processing.

The storage unit 124 includes one or more storage devices such as a read only memory (ROM), a random access memory (RAM), and a flash memory, and stores programs, data, and the like to be used in processes by the imaging unit 41, for example. The storage unit 124 associates coefficient set groups corresponding to the above coefficients α1 to α3, β1 to β3, and γ1 to γ3 with various object distances, and stores the coefficient set groups, for example. More specifically, the storage unit 124 stores, for each object surface 102 at each object distance, a coefficient set group including coefficients for the respective pixels 121a of the imaging device 121 with respect to the respective point light sources set on the object surface 102, for example.

The communication unit 125 communicates with the front camera ECU 42 by a predetermined communication method.

### [First Example Configuration of the Imaging Device 121]

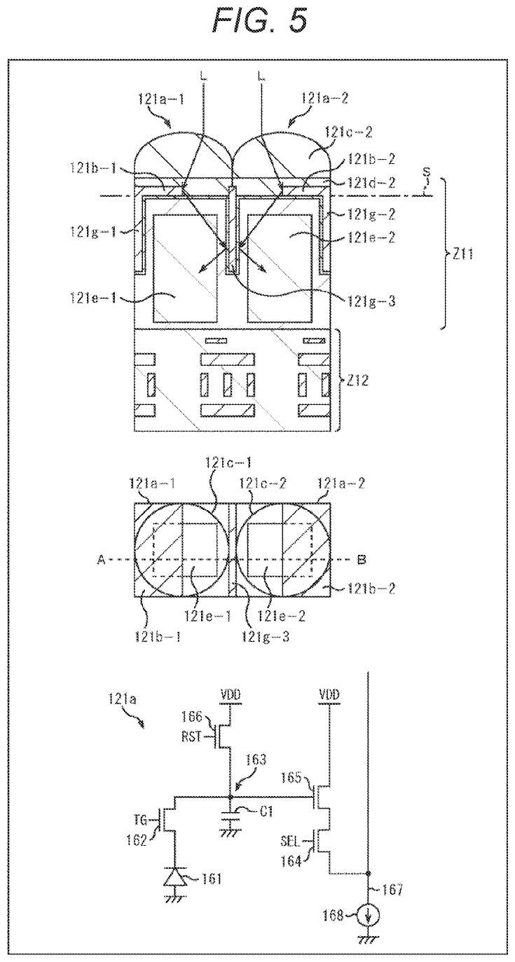

Next, a first example configuration of the imaging device 121 of the imaging unit 41 shown in FIG. 2 is described with reference to FIGS. 4 and 5.

FIG. 4 shows a front view of part of the pixel array unit of the imaging device 121. Note that FIG. 4 shows an example case where the number of pixels in the pixel array unit is 6×6. However, the number of pixels in the pixel array unit is not limited to this. Also, the example configuration of the pixel array unit shown in FIG. 4 is for explaining the first example configuration of the imaging device 121, and an actual example configuration of the pixel array unit will be described later.

In the imaging device 121 shown in FIG. 4, a light shielding film 121b that is one of modulation elements is provided for each pixel 121a so as to cover part of the light receiving region (light receiving surface) of the photodiode, and incident light entering each pixel 121a is optically modulated in accordance with the incident angle. The light shielding film 121b is then provided in a different region for each pixel 121a, the light-receiving sensitivity with respect to the incident angle of incident light varies with each pixel 121a, and each pixel 121a has a different incident angle directivity, for example.

For example, in a pixel 121a-1 and a pixel 121a-2, the ranges in which the light receiving regions of the photodiodes are shielded from light by a light shielding film 121b-1 and a light shielding film 121b-2 are different (at least the light shielding regions (positions) or the light shielding areas are different). Specifically, in the pixel 121a-1, the light shielding film 121b-1 is provided so as to shield part of the left-side portion of the light receiving region of the photodiode from light by a predetermined width. On the other hand, in the pixel 121a-2, the light shielding film 121b-2 is provided so as to shield part of the right-side portion of the light receiving region from light by a predetermined width. Note that the width by which the light shielding film 121b-1 shields the light receiving region of the photodiode from light and the width by which the light shielding film 121b-2 shields the light receiving region of the photodiode from light may be different or may be the same. Likewise, in the other pixels 121a, the light shielding films 121b are randomly disposed in the pixel array unit so as to shield a different region in the light receiving region from light for each pixel.

The top portion of FIG. 5 is a side cross-sectional view of the first example configuration of the imaging device 121, and the middle portion of FIG. 5 is a top view of the first example configuration of the imaging device 121. The side cross-sectional view in the top portion of FIG. 5 is also an A-B cross-section in the middle portion of FIG. 5. Further, the bottom portion of FIG. 5 shows an example circuit configuration of the imaging device 121.

In the imaging device 121 in the top portion of FIG. 5, incident light enters from the top side toward the bottom side of the drawing. The adjacent pixels 121a-1 and 121a-2 are of a so-called back-illuminated type, having a wiring layer Z12 provided as the lowermost layer in the drawing and a photoelectric conversion layer Z11 provided thereon.

Note that, in the description below, in a case where there is no need to distinguish the pixels 121a-1 and 121a-2 from each other, the number at the end of each reference numeral will be omitted, and the pixels will be simply referred to as the pixels 121a. In the description below, numbers and alphabets at the end of reference numerals might be omitted too for other components in the specification.

Further, FIG. 5 shows a side view and a top view of only two of the pixels constituting the pixel array unit of the imaging device 121, and more pixels 121a are of course also provided but are not shown in the drawings.

The pixels 121a-1 and 121a-2 further include photodiodes 121e-1 and 121e-2, respectively, as photoelectric conversion elements in the photoelectric conversion layer Z11. Furthermore, on the photodiodes 121e-1 and 121e-2, on-chip lenses 121c-1 and 121c-2, and color filters 121d-1 and 121d-2 are stacked in this order from the top.

The on-chip lenses 121c-1 and 121c-2 condense incident light onto the photodiodes 121e-1 and 121e-2.

The color filters 121d-1 and 121d-2 are optical filters that transmit light of a specific wavelength such as red, green, blue, infrared, and white, for example. Note that, in the case of white, the color filters 121d-1 and 121d-2 may be transparent filters, or may not be provided.

In the photoelectric conversion layer Z11 of the pixels 121a-1 and 121a-2, light shielding films 121g-1 to 121g-3 are formed at boundaries between the respective pixels, and prevent incident light L from entering the adjacent pixels and causing crosstalk, as shown in FIG. 5, for example.

Further, as shown in the top and the middle portions of FIG. 5, the light shielding films 121b-1 and 121b-2 shield part of the light receiving surface S from light as viewed from above. On the light receiving surface S of the photodiodes 121e-1 and 121e-2 in the pixels 121a-1 and 121a-2, different regions are shielded from light by the light shielding films 121b-1 and 121b-2, so that a different incident angle directivity is set independently for each pixel. However, the regions to be shielded from light do not need to be different among all the pixels 121a of the imaging device 121, and there may be some pixels 121a among which the same region is shielded from light.

Note that, as shown in the top portion of FIG. 5, the light shielding film 121b-1 and the light shielding film 121g-1 are connected to each other, and are arranged in an L shape when viewed from the side. Likewise, the light shielding film 121b-2 and the light shielding film 121g-2 are connected to each other, and are arranged in an L shape when viewed from the side. Further, the light shielding film 121b-1, the light shielding film 121b-2, and the light shielding films 121g-1 to 121g-3 are formed with a metal, and, for example, are formed with tungsten (W), aluminum (Al), or an alloy of Al and copper (Cu). Also, the light shielding film 121b-1, the light shielding film 121b-2, and the light shielding films 121g-1 to 121g-3 may be simultaneously formed with the same metal as the wiring lines in the same process as the process of forming the wiring lines in a semiconductor process. Note that the thicknesses of the light shielding film 121b-1, the light shielding film 121b-2, and the light shielding films 121g-1 to 121g-3 may not be the same depending on positions.

Further, as shown in the bottom portion of FIG. 5, a pixel 121a includes a photodiode 161 (corresponding to the photodiode 121e), a transfer transistor 162, a floating diffusion (FD) unit 163, a select transistor 164, an amplification transistor 165, and a reset transistor 166, and is connected to a current source 168 via a vertical signal line 167.

The anode electrode of the photodiode 161 is grounded, and the cathode electrode of the photodiode 161 is connected to the gate electrode of the amplification transistor 165 via the transfer transistor 162.

The transfer transistor 162 is driven in accordance with a transfer signal TG. For example, when the transfer signal TG supplied to the gate electrode of the transfer transistor 162 switches to the high level, the transfer transistor 162 is turned on. As a result, the electric charge accumulated in the photodiode 161 is transferred to the FD unit 163 via the transfer transistor 162.

The FD unit 163 is a floating diffusion region that has a charge capacity C1 and is provided between the transfer transistor 162 and the amplification transistor 165, and temporarily accumulates the electric charge transferred from the photodiode 161 via the transfer transistor 162. The FD unit 163 is a charge detection unit that converts electric charge into voltage, and the electric charge accumulated in the FD unit 163 is converted into voltage at the amplification transistor 165.

The select transistor 164 is driven in accordance with a select signal SEL. When the select signal SEL supplied to the gate electrode of the select transistor 164 is switched to the high level, the select transistor 164 is turned on, to connect the amplification transistor 165 and the vertical signal line 167.

The amplification transistor 165 serves as the input unit for a source follower that is a readout circuit that reads out a signal obtained through photoelectric conversion performed at the photodiode 161, and outputs a detection signal (pixel signal) at the level corresponding to the electric charge accumulated in the FD unit 163, to the vertical signal line 167. That is, the amplification transistor 165 has its drain terminal connected to a power supply VDD, and its source terminal connected to the vertical signal line 167 via the select transistor 164, to form a source follower together with the current source 168 connected to one end of the vertical signal line 167. The value (output pixel value) of the detection signal is modulated in accordance with the incident angle of incident light from the object, and has characteristics (directivity) that vary with the incident angle (or has an incident angle directivity).

The reset transistor 166 is driven in accordance with a reset signal RST. For example, when the reset signal RST supplied to the gate electrode of the reset transistor 166 is switched to the high level, the electric charge accumulated in the FD unit 163 is released to the power supply VDD, so that the FD unit 163 is reset.

Note that the shape of the light shielding film 121b of each pixel 121a is not limited to the example shown in FIG. 4, but can have any appropriate shape. For example, it is possible to adopt a shape extending in the horizontal direction in FIG. 4, an L shape extending in the vertical direction and the horizontal direction, a shape having a rectangular opening, or the like.

### [Second Example Configuration of the Imaging Device 121]

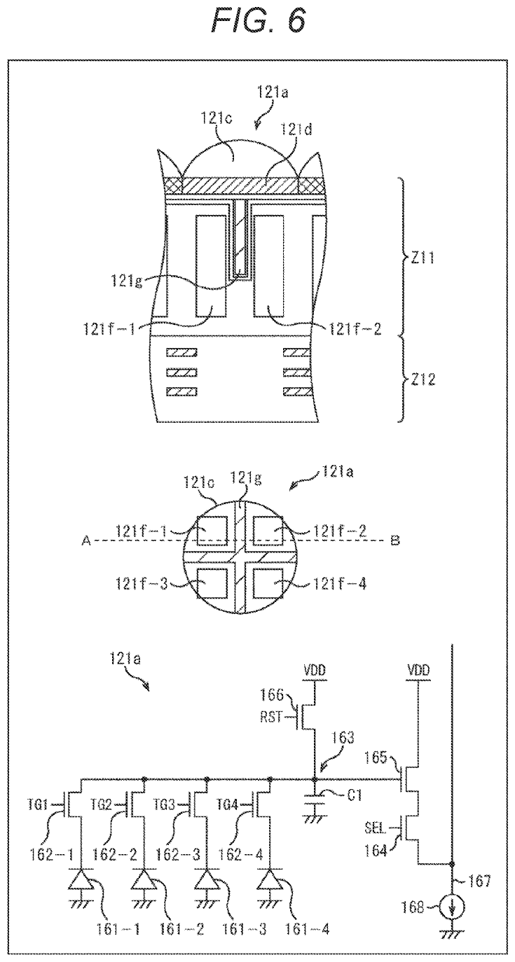

FIG. 6 is a diagram showing a second example configuration of the imaging device 121. The top portion of FIG. 6 shows a side cross-sectional view of a pixel 121a of the imaging device 121 as the second example configuration, and the middle portion of FIG. 6 shows a top view of the imaging device 121. The side cross-sectional view in the top portion of FIG. 6 is also an A-B cross-section in the middle portion of FIG. 6. Further, the bottom portion of FIG. 6 shows an example circuit configuration of the imaging device 121.

The configuration of the imaging device 121 in FIG. 6 differs from that of the imaging device 121 in FIG. 5 in that four photodiodes 121f-1 to 121f-4 are formed in one pixel 121a, and a light shielding film 121g is formed in a region that separates the photodiodes 121f-1 to 121f-4 from one another. That is, in the imaging device 121 in FIG. 6, the light shielding film 121g is formed in a cross shape as viewed from above. Note that the same components as those shown in FIG. 5 are denoted by the same reference numerals as those in FIG. 5, and detailed explanation of them is not made herein.

In the imaging device 121 in FIG. 6, the photodiodes 121f-1 to 121f-4 are separated by the light shielding film 121g, so that occurrence of electrical and optical crosstalk among the photodiodes 121f-1 to 121f-4 is prevented. That is, like the light shielding films 121g of the imaging device 121 in FIG. 5, the light shielding film 121g in FIG. 6 is for preventing crosstalk, and is not for providing an incident angle directivity.

Further, in the imaging device 121 in FIG. 6, one FD unit 163 is shared among the four photodiodes 121f-1 to 121f-4. The bottom portion of FIG. 6 shows an example circuit configuration in which one FD unit 163 is shared among the four photodiodes 121f-1 to 121f-4. Note that, as for the bottom portion of FIG. 6, explanation of the same components as those shown in the bottom portion of FIG. 5 is not made herein.

The circuit configuration shown in the bottom portion of FIG. 6 differs from that shown in the bottom portion of FIG. 5 in that photodiodes 161-1 to 161-4 (corresponding to the photodiodes 121f-1 to 121f-4 in the top portion of FIG. 6) and transfer transistors 162-1 to 162-4 are provided in place of the photodiode 161 (corresponding to the photodiode 121e in the top portion of FIG. 5) and the transfer transistor 162, and the FD unit 163 is shared.

With such a configuration, the electric charges accumulated in the photodiodes 121f-1 to 121f-4 is transferred to the common FD unit 163 having a predetermined capacity provided in the connecting portion between the photodiodes 121f-1 to 121f-4 and the gate electrode of the amplification transistor 165. A signal corresponding to the level of the electric charge retained in the FD unit 163 is then read as a detection signal (pixel signal).

Accordingly, the electric charges accumulated in the photodiodes 121f-1 to 121f-4 can be made to selectively contribute to the output of the pixel 121a, or the detection signal in various combinations. That is, electric charges can be read independently from each of the photodiodes 121f-1 to 121f-4, and the photodiodes 121f-1 to 121f-4 to contribute to outputs (or the degrees of contribution of the photodiodes 121f-1 to 121f-4 to outputs) are made to differ from one another. Thus, different incident angle directivities can be obtained.

For example, the electric charges in the photodiode 121f-1 and the photodiode 121f-3 are transferred to the FD unit 163, and the signals obtained by reading the respective electric charges are added, so that an incident angle directivity in the horizontal direction can be obtained. Likewise, the electric charges in the photodiode 121f-1 and the photodiode 121f-2 are transferred to the FD unit 163, and the signals obtained by reading the respective electric charges are added, so that an incident angle directivity in the vertical direction can be obtained.

Further, a signal obtained on the basis of the electric charges selectively read out independently from the four photodiodes 121f-1 to 121f-4 is a detection signal corresponding to one pixel of a detection image.

Note that contribution of (the electric charge in) each photodiode 121f to a detection signal depends not only on whether or not the electric charge (detection value) in each photodiode 121f is to be transferred to the FD unit 163, but also on resetting of the electric charges accumulated in the photodiodes 121f before the transfer to the FD unit 163 using an electronic shutter function or the like, for example. For example, if the electric charge in a photodiode 121f is reset immediately before the transfer to the FD unit 163, the photodiode 121f does not contribute to a detection signal at all. On the other hand, time is allowed between resetting the electric charge in a photodiode 121f and transfer of the electric charge to the FD unit 163, so that the photodiode 121f partially contributes to a detection signal.

As described above, in the case of the imaging device 121 in FIG. 6, the combination to be used for a detection signal is changed among the four photodiodes 121f-1 to 121f-4, so that a different incident angle directivity can be provided for each pixel. Further, a detection signal that is output from each pixel 121a of the imaging device 121 in FIG. 6 has a value (output pixel value) modulated in accordance with the incident angle of incident light from the object, and has characteristics (directivity) that vary with the incident angle (has an incident angle directivity).

Note that, in the imaging device 121 in FIG. 6, incident light is enters all the photodiodes 121f-1 to 121f-4 without being optically modulated. Therefore, a detection signal is not a signal obtained by optical modulation. Meanwhile, a photodiode 121f that does not contribute to a detection signal will be hereinafter also referred to as a photodiode 121f that does not contribute to the pixel or its output.

Further, FIG. 6 shows an example in which the light receiving surface of a pixel (a pixel 121a) is divided into four equal regions, and the photodiodes 121f each having a light receiving surface of the same size are disposed in the respective regions, or an example in which a photodiode is divided into four equal portions. However, the number of divisions and dividing positions of a photodiode can be set as appropriate.

For example, a photodiode is not necessarily divided into equal portions, and the dividing positions of the photodiode may vary with each pixel. Therefore, even if the photodiodes 121f at the same position among a plurality of pixels are made to contribute to outputs, for example, the incident angle directivity varies among the pixels. Also, the number of divisions is made to vary among the pixels, for example, incident angle directivities can be set more freely. Further, both the number of divisions and the dividing positions may be made to vary among the pixels, for example.

Furthermore, both the imaging device 121 in FIG. 5 and the imaging device 121 in FIG. 6 have a configuration in which each pixel can have an incident angle directivity that is set independently. Note that, in the imaging device 121 in FIG. 5, the incident angle directivity of each pixel is set at the time of manufacturing by the light shielding film 121b. In the imaging device 121 in FIG. 6, on the other hand, the number of divisions and the dividing position of the photodiode of each pixel are set at the time of manufacturing, but the incident angle directivity (the combination of photodiodes to contribute to an output) of each pixel can be set at a time of use (for example, at a time of imaging). Note that, in both the imaging device 121 in FIG. 5 and the imaging device 121 in FIG. 6, not all the pixels necessarily need to have an incident angle directivity.

Note that, as for the imaging device 121 in FIG. 5, the shape of the light shielding film 121b of each pixel 121a will be hereinafter referred to as a light shielding pattern. Meanwhile, as for the imaging device 121 of FIG. 6, the shape of the region of a photodiode 121f that does not contribute to an output in each pixel 121a will be hereinafter referred to as a light shielding pattern.

<Basic Characteristics and the Like of the Imaging Device 121>

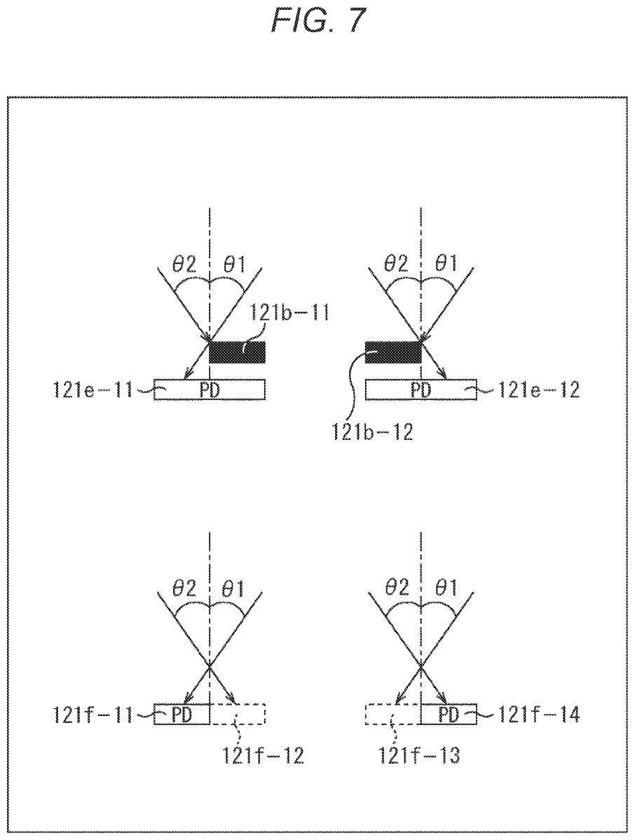

Next, the basic characteristics and the like of the imaging device 121 are described with reference to FIGS. 7 to 14.

<Principles of Generating an Incident Angle Directivity>

The incident angle directivity of each pixel of the imaging device 121 is generated by the principles illustrated in FIG. 7, for example. Note that the top left portion and the top right portion of FIG. 7 are diagrams for explaining the principles of generation of an incident angle directivity in the imaging device 121 shown in FIG. 5. The bottom left portion and the bottom right portion of FIG. 7 are diagrams for explaining the principles of generation of an incident angle directivity in the imaging device 121 shown in FIG. 6.

Each of the pixels in the top left portion and the top right portion of FIG. 7 includes one photodiode 121e. On the other hand, each of the pixels in the bottom left portion and the bottom right portion of FIG. 7 includes two photodiodes 121f. Note that an example in which one pixel includes two photodiodes 121f is shown herein, for ease of explanation. However, the number of photodiodes 121f included in one pixel may be other than two.

In the pixel shown in the top left portion of FIG. 7, a light shielding film 121b-11 is formed so as to shield the right half of the light receiving surface of the photodiode 121e-11. Meanwhile, in the pixel shown in the top right portion of FIG. 7, a light shielding film 121b-12 is formed so as to shield the left half of the light receiving surface of the photodiode 121e-12. Note that each dot-and-dash line in the drawing is an auxiliary line that passes through the center of the light receiving surface of the photodiode 121e in the horizontal direction and is perpendicular to the light receiving surface.

For example, in the pixel shown in the top left portion of FIG. 7, incident light from upper right that forms an incident angle θ1 with the dot-and-dash line in the drawing is easily received by the left half region of the photodiode 121e-11 that is not shielded from light by the light shielding film 121b-11. On the other hand, incident light from upper left that forms an incident angle θ2 with the dot-and-dash line in the drawing is hardly received by the left half region of the photodiode 121e-11 that is not shielded from light by the light shielding film 121b-11. Accordingly, the pixel shown in the top left portion of FIG. 7 has an incident angle directivity with a high light-receiving sensitivity to incident light from upper right in the drawing and a low light-receiving sensitivity to incident light from upper left.

Meanwhile, in the pixel shown in the top right portion of FIG. 7, for example, incident light from upper right that forms the incident angle θ1 is hardly received by the left half region of the photodiode 121e-12 shielded from light by the light shielding film 121b-12. On the other hand, incident light from upper left that forms the incident angle θ2 with the dot-and-dash line is easily received by the right half region of the photodiode 121e-12 that is not shielded from light by the light shielding film 121b-12. Accordingly, the pixel shown in the top right portion of FIG. 7 has an incident angle directivity with a low light-receiving sensitivity to incident light from upper right in the drawing and a high light-receiving sensitivity to incident light from upper left.

Further, in the pixel shown in the bottom left portion of FIG. 7, photodiodes 121f-11 and 121f-12 are provided on the right and left sides in the drawing, and one of the detection signals is read. Thus, the pixel has an incident angle directivity, without any light shielding film 121b.

Specifically, in the pixel shown in the bottom left portion of FIG. 7, only the signal of the photodiode 121f-11 provided on the left side in the drawing is read out. Thus, an incident angle directivity similar to that of the pixel shown in the top left portion of FIG. 7 can be obtained. That is, incident light from upper right that forms the incident angle θ1 with the dot-and-dash line in the drawing enters the photodiode 121f-11, and the signal corresponding to the amount of received light is read out from the photodiode 121f-11. Thus, the incident light contributes to the detection signal to be output from this pixel. On the other hand, incident light from upper left that forms the incident angle θ2 with the dot-and-dash line in the drawing enters the photodiode 121f-12, but is not read out from the photodiode 121f-12. Therefore, the incident light does not contribute to the detection signal to be output from this pixel.

Likewise, in a case where two photodiodes 121f-13 and 121f-14 are included as in the pixel shown in the bottom right portion of FIG. 7, only the signal of the photodiode 121f-14 provided on the right side in the drawing is read out, so that an incident angle directivity similar to that of the pixel shown in the top right portion of FIG. 7 can be obtained. That is, incident light from upper right that forms the incident angle θ1 enters the photodiode 121f-13, but any signal is not read out from the photodiode 121f-13. Therefore, the incident light does not contribute to the detection signal to be output from this pixel. On the other hand, incident light from upper left that forms the incident angle θ2 enters the photodiode 121f-14, and the signal corresponding to the amount of received light is read out from the photodiode 121f-14. Thus, the incident light contributes to the detection signal to be output from this pixel.

Note that, in each pixel shown in the top portions of FIG. 7, the region shielded from light and the region not shielded from light are divided at the center position of (the light receiving surface of the photodiode 121e of) the pixel in the horizontal direction in the example described above. However, the regions may be divided at some other position. Meanwhile, in each pixel shown in the bottom portions of FIG. 7, the two photodiodes 121f are divided at the center position of the pixel in the horizontal direction in the example described above. However, the two photodiodes may be divided at some other position. As the light-shielded region or the position at which the photodiodes 121f are divided is changed in the above manner, different incident angle directivities can be generated.

<Incident Angle Directivities in Configurations Including On-Chip Lenses>

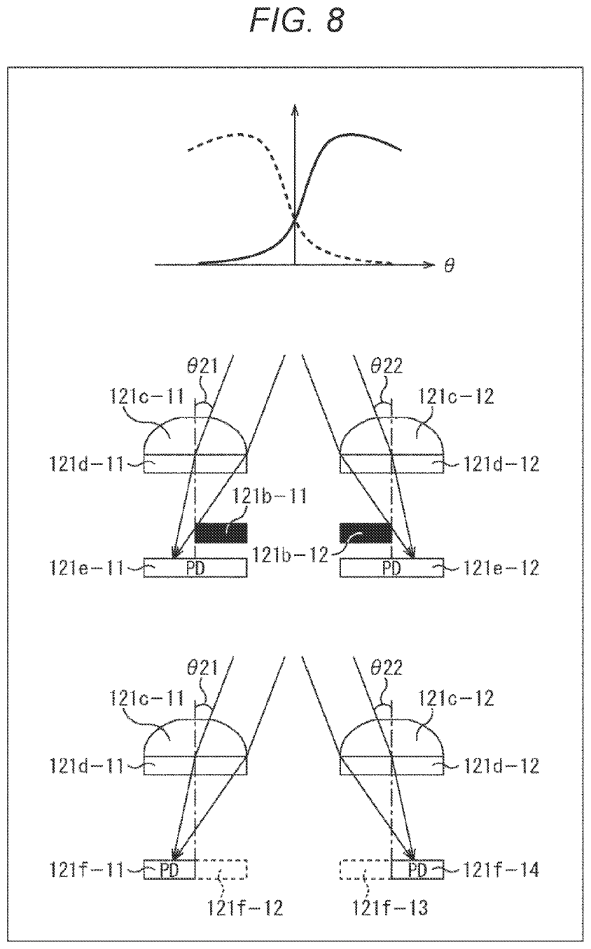

Next, incident angle directivities in configurations including on-chip lenses 121c are described with reference to FIG. 8.

The graph in the top portion of FIG. 8 shows the incident angle directivities of the pixels shown in the middle and bottom portions of FIG. 8. Note that the abscissa axis indicates incident angle θ, and the ordinate axis indicates detection signal level. Note that the incident angle θ is 0 degrees in a case where the direction of incident light coincides with the dot-and-dash line on the left side of the middle part of FIG. 8, the incident angle θ 21 side on the left side in the middle portion of FIG. 8 is a positive direction, and the side of an incident angle θ22 on the right side in the middle portion of FIG. 8 is a negative direction. Accordingly, the incident angle of incident light entering the on-chip lens 121c from upper right is greater than that of incident light entering from upper left. That is, the incident angle θ is greater when the inclination of the traveling direction of incident light to the left is greater (or the incident angle θ increases in the positive direction), and the incident angle θ is smaller when the inclination of the traveling direction of incident light to the right is greater (or the incident angle θ increases in the negative direction).

Meanwhile, the pixel shown in the middle left portion of FIG. 8 is obtained by adding an on-chip lens 121c-11 that condenses incident light and a color filter 121d-11 that transmits light of a predetermined wavelength, to the pixel shown in the top left portion of FIG. 7. That is, in this pixel, the on-chip lens 121c-11, the color filter 121d-11, the light shielding film 121b-11, and the photodiode 121e-11 are stacked in this order from the incident direction of light from above in the drawing.

Likewise, the pixel shown in the middle right portion of FIG. 8, the pixel shown in the bottom left portion of FIG. 8, and the pixel shown in the bottom right portion of FIG. 8 are obtained by adding an on-chip lens 121c-11 and a color filter 121d-11, or an on-chip lens 121c-12 and a color filter 121d-12 to the pixel shown in the top right portion of FIG. 7, the pixel shown in the bottom left portion of FIG. 7, and the pixel shown in the bottom right portion of FIG. 7, respectively.

In the pixel shown in the middle left portion of FIG. 8, as indicated by the solid-line waveform in the top portion of FIG. 8, the detection signal level (light-receiving sensitivity) of the photodiode 121e-11 varies depending on the incident angle θ of incident light. That is, when the incident angle θ, which is the angle formed by incident light with respect to the dot-and-dash line in the drawing, is greater (or when the incident angle θ is greater in the positive direction (or inclines to the right in the drawing)), light is condensed in the region in which the light shielding film 121b-11 is not provided, and accordingly, the detection signal level of the photodiode 121e-11 becomes higher. Conversely, when the incident angle θ of incident light is smaller (or when the incident angle θ is greater in the negative direction (as inclines to the left in the drawing)), light is condensed in the region in which the light shielding film 121b-11 is provided, and accordingly, the detection signal level of the photodiode 121e-11 becomes lower.

Also, in the pixel shown in the middle right portion of FIG. 8, as indicated by the dashed-line waveform in the top portion of FIG. 8, the detection signal level (light-receiving sensitivity) of the photodiode 121e-12 varies depending on the incident angle θ of incident light. Specifically, when the incident angle θ of incident light is greater (or when the incident angle θ is greater in the positive direction), light is condensed in the region in which the light shielding film 121b-12 is provided, and accordingly, the detection signal level of the photodiode 121e-12 becomes lower. Conversely, when the incident angle θ of incident light is smaller (or when the incident angle θ is greater in the negative direction), light is condensed in the region in which the light shielding film 121b-12 is not provided, and accordingly, the detection signal level of the photodiode 121e-12 becomes higher.

The solid-line and dashed-line waveforms shown in the top portion of FIG. 8 can be made to vary depending on the region of the light shielding film 121b. Accordingly, different incident angle directivities that vary with the respective pixels can be generated, depending on the region of the light shielding film 121b.

As described above, an incident angle directivity is the characteristics of the light-receiving sensitivity of each pixel depending on the incident angle θ, but it can also be said that this is the characteristics of the light shielding value depending on the incident angle θ in each pixel in the middle portions of FIG. 8. That is, the light shielding film 121b blocks incident light in a specific direction at a high level, but cannot sufficiently block incident light from other directions. The changes caused in level by this light shielding generates detection signal levels that vary with the incident angle θ as shown in the top portion of FIG. 8. Therefore, when the direction in which light can be blocked at the highest level in each pixel is defined as the light shielding direction of each pixel, the respective pixels having different incident angle directivities from one another means the respective pixels having different light shielding directions from one another.

Further, in the pixel shown in the bottom left portion of FIG. 8, only the signal of the photodiode 121f-11 in the left portion of the drawing is used, so that an incident angle directivity similar to that of the pixel shown in the middle left portion of FIG. 8 can be obtained, as in the pixel shown in the bottom left portion of FIG. 7. That is, as the incident angle θ of incident light becomes greater (or as the incident angle θ becomes greater in the positive direction), light is condensed in the region of the photodiode 121f-11 from which the signal is to be read, and accordingly, the detection signal level becomes higher. Conversely, as the incident angle θ of incident light is smaller (or as the incident angle θ is greater in the negative direction), light is condensed in the region of the photodiode 121f-12 from which the signal is not to be read, and accordingly, the detection signal level becomes lower.

Further, likewise, in the pixel shown in the bottom right portion of FIG. 8, only the signal of the photodiode 121f-14 in the right portion of the drawing is used, so that an incident angle directivity similar to that of the pixel shown in the middle right portion of FIG. 8 can be obtained, as in the pixel shown in the bottom right portion of FIG. 7. That is, when the incident angle θ of incident light is greater (or when the incident angle θ is greater in the positive direction), light is condensed in the region of the photodiode 121f-13 that does not contribute to the output (detection signal), and accordingly, the level of the detection signal of each pixel becomes lower. Conversely, when the incident angle θ of incident light is smaller (or when the incident angle θ is greater in the negative direction), light is condensed in the region of the photodiode 121f-14 that contributes to the output (detection signal), and accordingly, the level of the detection signal in each pixel becomes higher.

Here, the centroid of the incident angle directivity of a pixel 121a is defined as follows.

The centroid of the incident angle directivity is the centroid of the distribution of the intensity of incident light that enters the light receiving surface of the pixel 121a. The light receiving surface of the pixel 121a is the light receiving surface of the photodiode 121e in each pixel 121a shown in the middle portions of FIG. 8, and is the light receiving surface of the photodiode 121f in each pixel 121a shown in the bottom portions of FIG. 8.

For example, the detection signal level on the ordinate axis of the graph shown in the top portion of FIG. 8 is represented by a(θ), and a light beam having an incident angle θg calculated according to Equation (4) shown below is a centroidal light beam.

θg=Σ(a(θ)×θ)/Σa(θ) (4)

Further, the point at which the centroidal light beam intersects the light receiving surface of the pixel 121a is the centroid of the incident angle directivity of the pixel 121a.

Also, as in the pixels shown in the bottom portions of FIG. 8, in a pixel that includes a plurality of photodiodes so as to be able to change the photodiode contributing to an output, each photodiode is made to have a directivity with respect to the incident angle of incident light. The on-chip lenses 121c need to be provided in each pixel so that an incident angle directivity is generated in each pixel.

Note that, in the description below, an example case where pixels 121a that achieve incident angle directivities using the light shielding films 121b like the pixel 121a shown in FIG. 5 will be mainly described. However, unless the light shielding films 121b are necessary, it is also possible to use pixels 121a that basically divides photodiodes to obtain incident angle directivities.

<Relationship Between Light-Shielded Region and Angle of View>

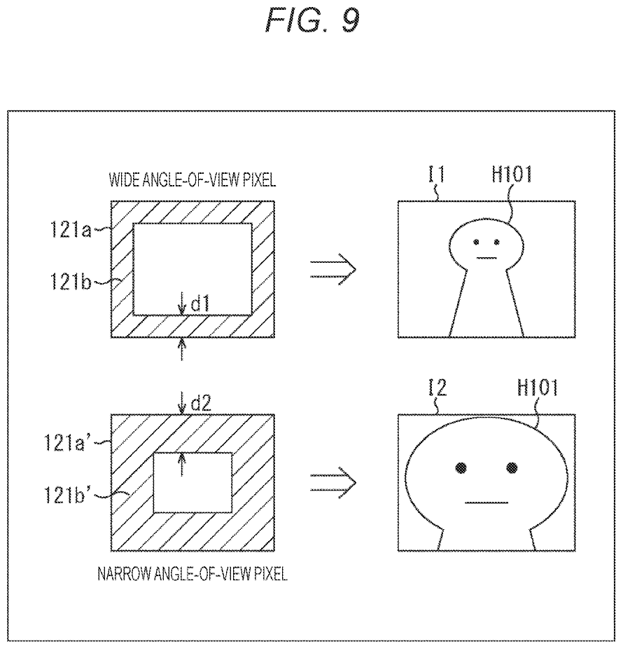

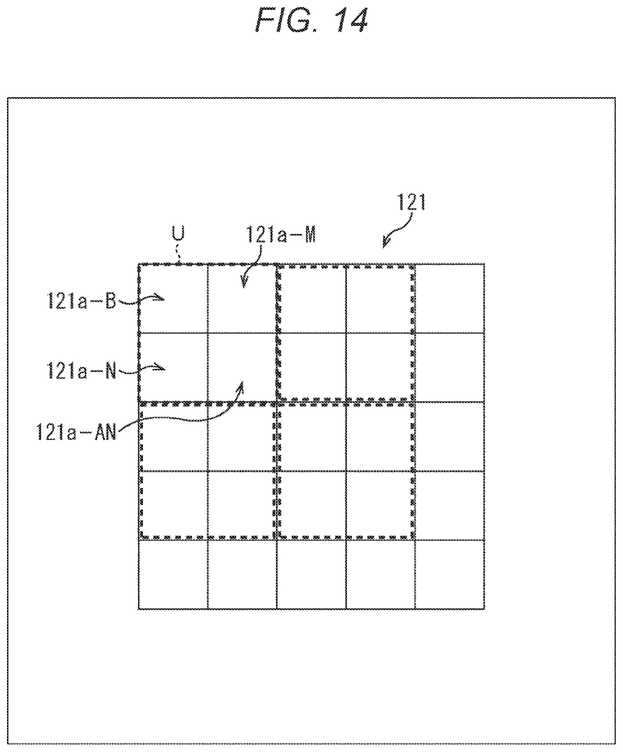

Next, the relationship between the light-shielded regions and the angles of view of pixels 121a is described with reference to FIGS. 9 and 14.

For example, a pixel 121a shielded from light by the light shielding film 121b by a width d1 from each edge of the four sides as shown in the top portion of FIG. 9, and a pixel 121a′ shielded from light by the light shielding film 121b by a width d2(>d1) from each edge of the four sides as shown in the bottom portion of FIG. 9 are now described.

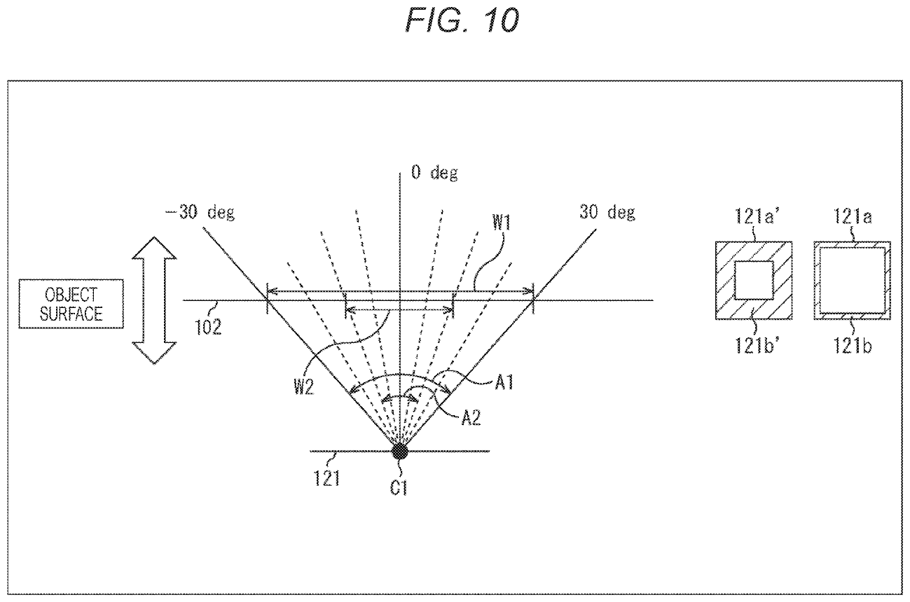

FIG. 10 shows an example of incident angles of incident light from the object surface 102 to the center position C1 of the imaging device 121. Note that FIG. 10 shows an example of incident angles of incident light in the horizontal direction, but similar incident angles are observed in the vertical direction. Further, the right portion of FIG. 10 shows the pixels 121a and 121a′ shown in FIG. 9.

For example, in a case where the pixel 121a shown in FIG. 9 is disposed at the center position C1 of the imaging device 121, the range of the incident angle of incident light from the object surface 102 to the pixel 121a is represented by an angle A1 as shown in the left portion of FIG. 10. Accordingly, the pixel 121a can receive incident light of the width W1 of the object surface 102 in the horizontal direction.

On the other hand, in a case where the pixel 121a′ in FIG. 9 is disposed at the center position C1 of the imaging device 121, the range of the incident angle of incident light from the object surface 102 to the pixel 121a′ is represented by an angle A2 (<A1) as shown in the left portion of FIG. 10, because the pixel 121a′ has a wider light-shielded region than the pixel 121a. Therefore, the pixel 121a′ can receive incident light of the width W2 (<W1) of the object surface 102 in the horizontal direction.

That is, the pixel 121a having a narrow light-shielded region is a wide angle-of-view pixel suitable for imaging a wide region on the object surface 102, while the pixel 121a′ having a wide light-shielded region is a narrow angle-of-view pixel suitable for imaging a narrow region on the object surface 102. Note that the wide angle-of-view pixel and the narrow angle-of-view pixel mentioned herein are expressions for comparing both the pixels 121a and 121a′ shown in FIG. 9, and are not limited to these pixels in comparing pixels having other angles of view.

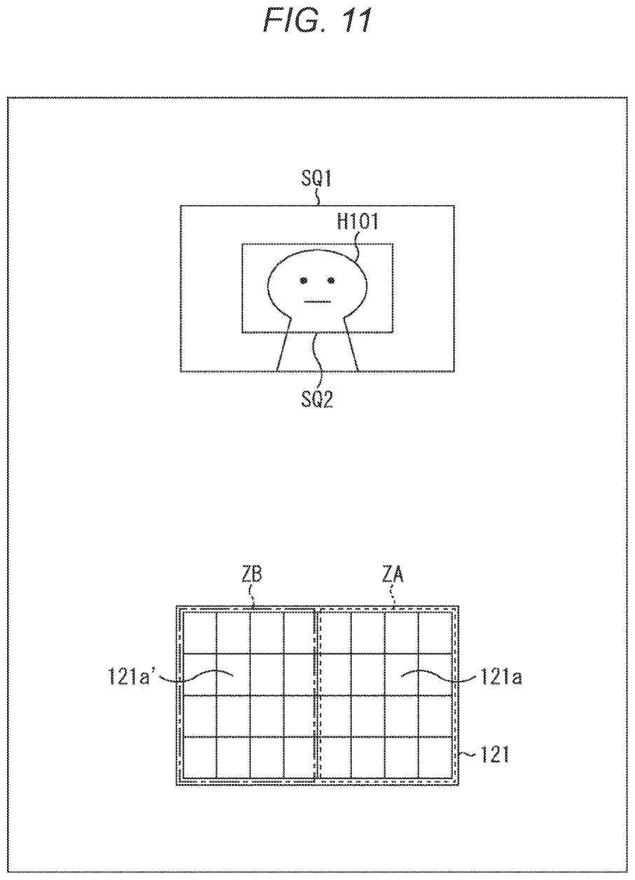

Therefore, the pixel 121a is used to restore an image I1 shown in FIG. 9, for example. The image I1 is an image that includes an entire person H101 as the object shown in the top portion of FIG. 11, and has an angle of view SQ1 corresponding to the object width W1. On the other hand, the pixel 121a′ is used to restore an image 12 shown in FIG. 9, for example. The image 12 is an image that shows the face of the person H101 shown in the top portion of FIG. 11 and the area surrounding the face in an enlarged manner, and has an angle of view SQ2 corresponding to the object width W2.

Meanwhile, as shown in the bottom portion of FIG. 11, it is possible to gather and arrange a predetermined number of pixels 121a shown in FIG. 9 in a region ZA surrounded by a dashed line in the imaging device 121, and a predetermined number of pixels 121a′ in a region ZB surrounded by a dot-and-dash line, for example. Further, when an image of the angle of view SQ1 corresponding to the object width W1 is to be restored, for example, the detection signals of the respective pixels 121a in the region ZA are used, so that the image of the angle of view SQ1 can be appropriately restored. On the other hand, when an image of the angle of view SQ2 corresponding to the object width W2 is to be restored, the detection signals of the respective pixels 121a′ in the region ZB are used, so that the image of the angle of view SQ2 can be appropriately restored.

Note that the angle of view SQ2 is smaller than the angle of view SQ1. Therefore, in a case where an image of the angle of view SQ2 and an image of the angle of view SQ1 are to be restored with the same number of pixels, it is possible to obtain a restored image with higher image quality by restoring the image of the angle of view SQ2 than by restoring the image of the angle of view SQ1.

That is, in a case where restored images are to be obtained with the same number of pixels, a restored image with higher image quality can be obtained by restoring an image with a smaller angle of view.

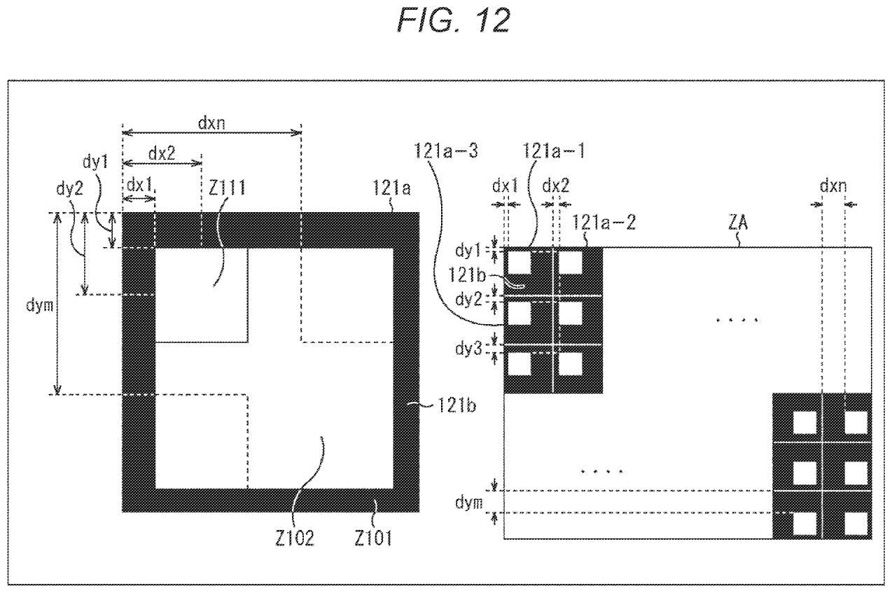

For example, the right portion of FIG. 12 shows an example configuration within the region ZA in the imaging device 121 shown in FIG. 11. The left portion of FIG. 12 shows an example configuration of a pixel 121a in the region ZA.

In FIG. 12, the regions in black are the light shielding films 121b, and the light-shielded region of each pixel 121a is determined in accordance with the rule shown in the left portion of FIG. 12, for example.

The principal light-shielded portion Z101 in the left portion of FIG. 12 (the black portion in the left portion of FIG. 12) is the region that is shielded from light in each pixel 121a. Specifically, the principal light-shielded portion Z101 is the region having a width dx1 from each of the right and left sides of the pixel 121a toward the inside of the pixel 121a, and is the region having a height dy1 from each of the top and bottom sides of the pixel 121a toward the inside of the pixel 121a. Further, in each pixel 121a, a rectangular opening Z111 that is not shielded from light by the light shielding film 121b is provided within a region Z102 on the inner side of the principal light-shielded portion Z101. Accordingly, in each pixel 121a, the region other than the opening Z111 is shielded from light by the light shielding film 121b.

Here, the openings Z111 of the respective pixels 121a are regularly arranged. Specifically, the position of the opening Z111 in the horizontal direction in each pixel 121a is the same among the pixels 121a in the same column in the vertical direction. Also, the position of the opening Z111 in each pixel 121a is the same among the pixels 121a in the same row in the horizontal direction.

On the other hand, the position of the opening Z111 in each pixel 121a in the horizontal direction is shifted by a predetermined distance in accordance with the position of the pixel 121a in the horizontal direction. That is, as the position of the pixel 121a becomes closer to the right, the left side of the opening Z111 moves to a position shifted to the right by a width dx1, dx2, . . . , and dxn from the left side of the pixel 121a. The distance between the width dx1 and the width dx2, the distance between the width dx2 and the width dx3, . . . , and the distance between the width dxn−1 and the width dxn each have the value obtained by dividing the length obtained by subtracting the width of the opening Z111 from the width of the region Z102 in the horizontal direction by the number n−1 of pixels in the horizontal direction.

Also, the position of the opening Z111 in each pixel 121a in the vertical direction is shifted by a predetermined distance in accordance with the position of the pixel 121a in the vertical direction. That is, as the position of the pixel 121a becomes closer to the bottom, the top side of the opening Z111 moves to a position shifted to the bottom by a height dy1, dy2, . . . , and dyn from the top side of the pixel 121a. The distance between the height dy1 and the height dy2, the distance between the height dy2 and the height dy3, . . . , and the distance between the height dyn−1 and the height dyn each have the value obtained by dividing the length obtained by subtracting the height of the opening Z111 from the height of the region Z102 in the vertical direction by the number m−1 of pixels in the vertical direction.

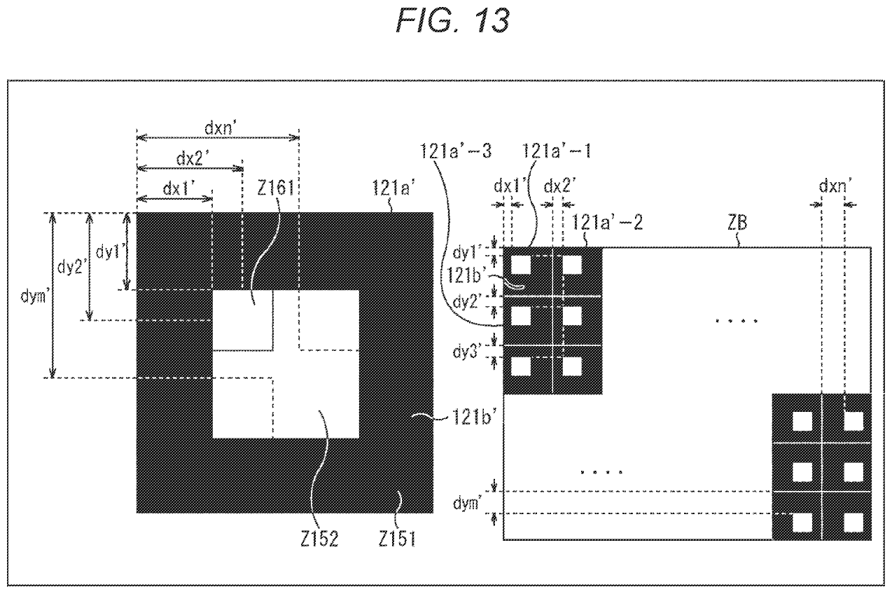

The right portion of FIG. 13 shows an example configuration within the region ZB in the imaging device 121 shown in FIG. 11. The left portion of FIG. 13 shows an example configuration of a pixel 121a′ in the region ZB.

In FIG. 13, the regions in black are the light shielding films 121b′, and the light-shielded region of each pixel 121a′ is determined in accordance with the rule shown in the left portion of FIG. 13, for example.

The principal light-shielded portion Z151 in the left portion of FIG. 13 (the black portion in the left portion of FIG. 13) is the region that is shielded from light in each pixel 121a′. Specifically, the principal light-shielded portion Z151 is the region having a width dx1′ from each of the right and left sides of the pixel 121a′ toward the inside of the pixel 121a′, and is the region having a height dy1′ from each of the top and bottom sides of the pixel 121a′ toward the inside of the pixel 121a′. Further, in each pixel 121a′, a rectangular opening Z161 that is not shielded from light by the light shielding film 121b′ is provided within a region Z152 on the inner side of the principal light-shielded portion Z151. Accordingly, in each pixel 121a′, the region other than the opening Z161 is shielded from light by the light shielding film 121b′.

Here, the openings Z161 of the respective pixels 121a′ are regularly arranged, like the openings Z111 of the respective pixels 121a shown in FIG. 12. Specifically, the position of the opening Z161 in the horizontal direction in each pixel 121a′ is the same among the pixels 121a′ in the same column in the vertical direction. Also, the position of the opening Z161 in each pixel 121a′ is the same among the pixels 121a′ in the same row in the horizontal direction.

On the other hand, the position of the opening Z161 in each pixel 121a′ in the horizontal direction is shifted by a predetermined distance in accordance with the position of the pixel 121a′ in the horizontal direction. That is, as the position of the pixel 121a′ becomes closer to the right, the left side of the opening Z161 moves to a position shifted to the right by a width dx1′, dx2′, . . . , and dxn′ from the left side of the pixel 121a′. The distance between the width dx1′ and the width dx2′, the distance between the width dx2′ and the width dx3′, . . . , and the distance between the width dxn−1′ and the width dxn′ each have the value obtained by dividing the length obtained by subtracting the width of the opening Z161 from the width of the region Z152 in the horizontal direction by the number n−1 of pixels in the horizontal direction.

Also, the position of the opening Z161 in each pixel 121a′ in the vertical direction is shifted by a predetermined distance in accordance with the position of the pixel 121a′ in the vertical direction. That is, as the position of the pixel 121a′ becomes closer to the bottom, the top side of the opening Z161 moves to a position shifted to the bottom by a height dy1′, dy2′, . . . , and dyn′ from the top side of the pixel 121a′. The distance between the height dy1′ and the height dy2′, the distance between the height dy2′ and the height dy3′, . . . , and the distance between the height dyn−1′ and the height dyn′ each have the value obtained by dividing the length obtained by subtracting the height of the opening Z161 from the height of the region Z152 in the vertical direction by the number m−1 of pixels in the vertical direction.

Here, the length obtained by subtracting the width of the opening Z111 from the width of the region Z102 in the horizontal direction in each pixel 121a shown in FIG. 12 is greater than the width obtained by subtracting the width of the opening Z161 from the width of the region Z152 in the horizontal direction in each pixel 121a′ shown in FIG. 13. Accordingly, the stepwise differences among the widths dx1, dx2, . . . , and dxn in FIG. 12 are larger than the stepwise differences among the widths dx1′, dx2′, . . . , and dxn′ in FIG. 13.

Also, the length obtained by subtracting the height of the opening Z111 from the height of the region Z102 in the vertical direction in each pixel 121a shown in FIG. 12 is greater than the length obtained by subtracting the height of the opening Z161 from the height of the region Z152 in the vertical direction in each pixel 121a′ shown in FIG. 13. Accordingly, the stepwise differences among the heights dy1, dy2, . . . , and dyn in FIG. 12 are larger than the stepwise differences among the heights dy1′, dy2′, and dyn′ in FIG. 13.

As described above, the stepwise differences in the positions in the horizontal direction and the vertical direction of the opening Z111 of the light shielding film 121b of each pixel 121a shown in FIG. 12 differ from the stepwise differences in the positions in the horizontal direction and the vertical direction of the opening Z161 of the light shielding film 121b′ of each pixel 121a′ shown in FIG. 13. The stepwise differences then turn into differences in object resolution (angular resolution) in restored images. That is, the stepwise differences in the positions in the horizontal direction and the vertical direction of the opening Z161 of the light shielding film 121b′ of each pixel 121a′ shown in FIG. 13 are smaller than the stepwise differences in the positions in the horizontal direction and the vertical direction of the opening Z111 of the light shielding film 121b of each pixel 121a shown in FIG. 12. Accordingly, a restored image restored with the use of the detection signals of the respective pixels 121a′ shown in FIG. 13 has a higher object resolution and a higher image quality than a restored image restored with the use of the detection signals of the respective pixels 121a shown in FIG. 12.

As the combination of the light-shielded region of the principal light-shielded portion and the opening region of the opening is varied as above, it becomes possible to obtain the imaging device 121 including pixels having various angles of view (or having various incident angle directivities).

Note that, in the example described above, the pixels 121a and the pixels 121a′ are separately arranged in the region ZA and the region ZB. However, this is for ease of explanation, and pixels 121a corresponding to different angles of view are preferably disposed in the same region.

For example, as shown in FIG. 14, four pixels formed with 2×2 pixels indicated by a dashed line are set as one unit U, and each unit U is formed with the four pixels: a pixel 121a-W having a wide angle of view, a pixel 121a-M having a medium angle of view, a pixel 121a-N having a narrow angle of view, and a pixel 121a-AN having a very narrow angle of view.

In this case, or in a case where the total number of pixels 121a is X, for example, it is possible to restore a restored image, using a detection image of a X/4 pixel for each of the four kinds of angles of view. At this stage, four kinds of coefficient set groups that vary with the respective angles of view are used, and restored images with different angles of view from one another are restored with four different simultaneous equations.

Accordingly, restored image are restored with the use of detection images obtained from the pixels suitable for imaging with the angles of view of the restored image to be restored, so that appropriate restored images for the four kinds of angles of view can be obtained.

Further, an image having an intermediate angle of view of the four angles of view, and images having angles of view around the intermediate angle of view may be generated by interpolation from images with the four angles of view, or pseudo optical zoom may be achieved by seamlessly generating images having various angles of view.

Note that, in a case where an image with a wide angle of view is to be obtained as a restored image, for example, all the wide angle-of-view pixels may be used, or some of the wide angle-of-view pixels may be used. Also, in a case where an image with a narrow angle of view is to be obtained as a restored image, for example, all the narrow angle-of-view pixels may be used, or some of the narrow angle-of-view pixels may be used.

<Example Installation of the Front Camera Module 21>

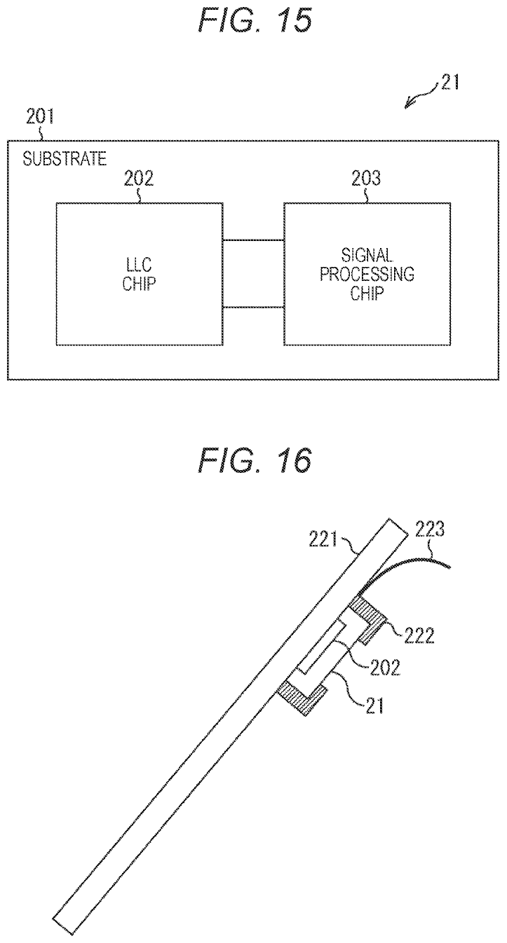

Next, example installation of the front camera module 21 is described with reference to FIGS. 15 to 17.

<Example Hardware Configuration of the Front Camera Module 21>

FIG. 15 shows an example hardware configuration of the front camera module 21.

In the front camera module 21 shown in FIG. 15, two semiconductor chips that are an LLC chip 202 and a signal processing chip 203 are mounted on the same substrate 201.

The LLC chip 202 is a semiconductor chip including the imaging unit 41 shown in FIG. 1.

The signal processing chip 203 is a semiconductor chip including the front camera ECU 42 and the MCU 43 shown in FIG. 1.

As the LLC chip 202 and the signal processing chip 203 are disposed on the same substrate 201 as described above, a flexible substrate becomes unnecessary, and unnecessary radiation is reduced.

<Method for Attaching the Front Camera Module 21>

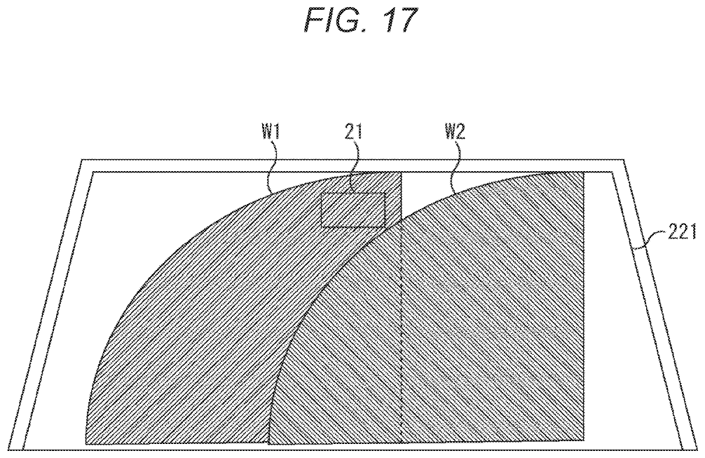

Next, an example method for attaching the front camera module 21 is described with reference to FIGS. 16 and 17. FIG. 16 is a side view of the windshield 221 of a vehicle to which the front camera module 21 is attached. FIG. 17 is a front view of the windshield 221.

The front camera module 21 is detachably attached with a bracket 222 so that the surface on which the LLC chip 202 is mounted extends along the surface on the vehicle interior side of the windshield 221. With this arrangement, the light receiving surface of the imaging device 121 provided on the surface of the LLC chip 202 faces and comes into contact with or close to the surface of the windshield 221 on the vehicle interior side, and becomes substantially parallel to the surface of the windshield 221 on the vehicle interior side.

Accordingly, the space between the light receiving surface of the imaging device 121 and the windshield 221 disappears, or becomes very narrow. As a result, reflection from the windshield 221 due to reflection of incident light, and dew condensation between the light receiving surface of the imaging device 121 and the windshield 221 are prevented.

The front camera module 21 is also connected to the bus B1 of the in-vehicle system 11 via a cable 223.

Note that the front camera module 21 is preferably installed at a position that does not block the field of view of an occupant such as the driver of the vehicle. Further, as shown in FIG. 17, the front camera module 21 is preferably installed at a position overlapping the region W1 or the region W2 from which water droplets of the windshield 221 are removed by the windshield wipers (not shown) of the vehicle. For example, the front camera module 21 is provided near the upper edge of the center of the windshield 221.

<First Embodiment of the Pixel Array Unit of the Imaging Device 121>

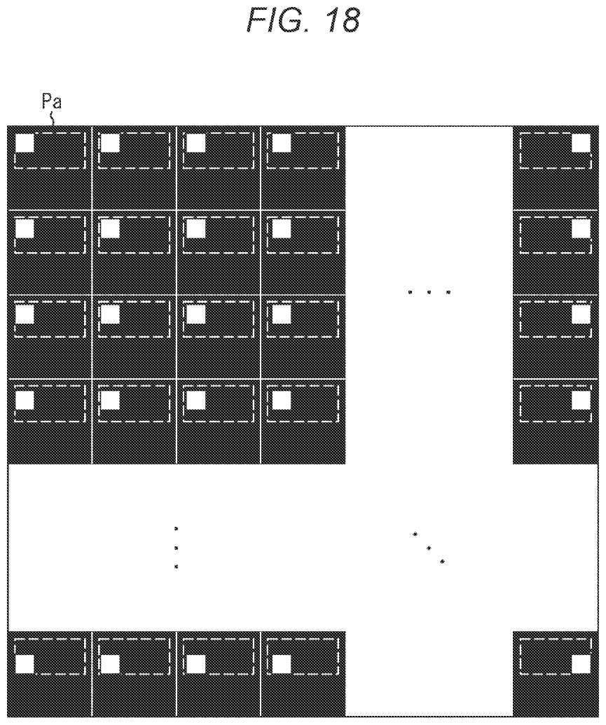

Next, the first embodiment of the pixel array unit of the imaging device 121 is described with reference to FIGS. 18 to 20.

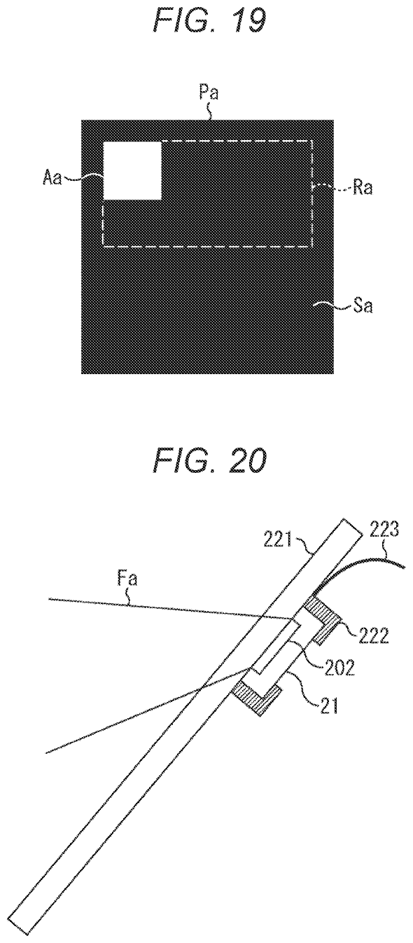

FIG. 18 shows the first embodiment of the light shielding pattern of the pixel array unit of the imaging device 121. FIG. 19 shows an example of the light shielding pattern of a pixel Pa that is the first embodiment of the pixels 121a constituting the pixel array unit shown in FIG. 18.

The opening Aa of the light shielding film Sa of each pixel Pa is set within a rectangular opening setting region Ra indicated by a dashed line. Accordingly, the region other than the opening setting region Ra of the light shielding film Sa of each pixel Pa serves as the principal light-shielded portion of the light shielding film Sa.

The size, the shape, and the position of the opening setting region Ra are common among the respective pixels Pa. The height of the opening setting region Ra in the vertical direction is smaller than ½ of the height of the pixel Pa, and the width thereof in the horizontal direction is slightly smaller than the width of the pixel Pa. Further, the opening setting region Ra is set at the center in the horizontal direction in the pixel Pa, and at a position closer to the top in the vertical direction. Accordingly, the centroid of the opening setting region Ra is biased upward from the center of the pixel Pa.

The shape and the size of the rectangular opening Aa are common among the respective pixels Pa. Also, the opening Aa is formed within the opening setting region Ra of each pixel Pa, in accordance with a rule similar to the rule described above with reference to FIGS. 12 and 13.

Specifically, the opening Aa is located at the left end of the opening setting region Ra in each pixel Pa in the left end column in the pixel array unit, and is located at the upper end of the opening setting region Ra in each pixel Pa in the upper end row in the pixel array unit. Further, as the position of the pixel Pa becomes closer to the right, the opening Aa shifts to the right at equal intervals within the opening setting region Ra, and is located at the right end of the opening setting region Ra in each pixel Pa in the right end column in the pixel array unit. Also, as the position of the pixel Pa becomes closer to the bottom, the opening Aa shifts to the bottom at equal intervals within the opening setting region Ra, and is located at the lower end of the opening setting region Ra in each pixel Pa in the lower end row in the pixel array unit.

Accordingly, the position of the opening Aa in the horizontal direction is the same in each pixel Pa in the same column in the vertical direction. Also, the position of the opening Aa in the vertical direction is the same in each pixel Pa in the same row in the horizontal direction. Accordingly, the position of the opening Aa in each pixel Pa, which is the position at which incident light enters each pixel Pa, varies with each pixel Pa, and, as a result, the incident angle directivities of the respective pixels Pa differ from one another.

Further, the openings Aa of the respective pixels Pa cover the opening setting region Ra. That is, the region in which the openings Aa of the respective pixels Pa are overlapped on one another is equal to the opening setting region Ra. Note that the layout pattern of the openings Aa is not limited to the above configuration, and may be any layout, as long as the region in which the openings Aa are overlapped on one another is equal to the opening setting region Ra. For example, the openings Aa may be randomly arranged within the opening setting region Ra.

Here, the centroid of the incident angle directivity of each pixel Pa substantially coincides with the centroid of the opening Aa of each pixel Pa, and is biased upward from the center of each pixel Pa. Accordingly, the average of the centroids of the incident angle directivities of the respective pixels Pa is biased upward from the centers of the pixels Pa. That is, the average of the incident angles of centroidal light beams in the respective pixels Pa is biased downward with respect to the normal direction of the light receiving surface of the pixel array unit.

Accordingly, the view in front of the vehicle can be imaged with an appropriate angle of view, even though the LLC chip 202 is installed parallel to the windshield 221, and the light receiving surface of the pixel array unit of the imaging device 121 faces upward. More specifically, as shown in FIG. 20, it is possible to image a field of view (FOV) Fa that extends obliquely downward in front of the vehicle. As a result, it becomes possible to monitor the view in front of the vehicle on the basis of the sensing image obtained by the imaging unit 41.

Note that the position of the opening setting region Ra, which is the offset of the centroid of the opening setting region Ra from the center of the pixel Pa, is set in accordance with the inclination of the windshield 221, the distance to the object to be imaged, and the like. Further, the shape and the size of the opening setting region Ra are set on the basis of the angle of view with which imaging is to be performed.

Furthermore, even if the LLC chip 202 (or the light receiving surface of the imaging device 121) does not face forward, the view in front of the vehicle can be imaged, and any imaging lens is unnecessary. Accordingly, as described above with reference to FIG. 15, the LLC chip 202 and the signal processing chip 203 are mounted on the same substrate, and the mounting surface of the LLC chip 202 of the front camera module 21 is brought into contact with or close to the windshield 221 so that the front camera module 21 can be attached to the windshield 221.

<Imaging Process by the Imaging Unit 41>

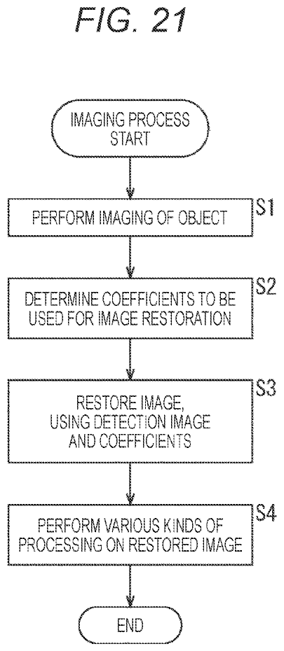

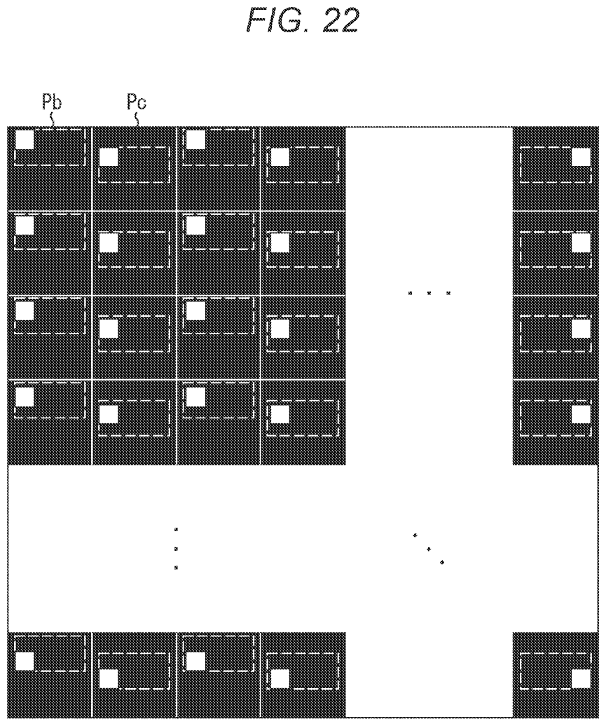

Next, an imaging process to be performed by the imaging unit 41 shown in FIG. 2 is described with reference to a flowchart shown in FIG. 21.

In step S1, the imaging device 121 images an object. As a result, a detection signal indicating the detection signal level corresponding to the amount of incident light from the object is output from each pixel 121a (pixel Pa) of the imaging device 121 having different incident angle directivities, and the imaging device 121 supplies a detection image formed with the detection signals of the respective pixels 121a to the restoration unit 122.

In step S2, the restoration unit 122 obtains coefficients to be used for image restoration. Specifically, the restoration unit 122 sets the distance to the object surface 102 to be restored, which is the object distance. Note that any method can be adopted as the method for setting the object distance. For example, the restoration unit 122 sets an object distance set by a user, or an object distance detected by various sensors as the distance to the object surface 102 to be restored.

Next, the restoration unit 122 reads, from the storage unit 124, the coefficient set group associated with the set object distance.

In step S3, the restoration unit 122 restores an image, using the detection image and the coefficients. Specifically, the restoration unit 122 creates the simultaneous equations described with reference to Equations (1) to (3) shown above, using the detection signal level of each pixel in the detection image and the coefficient set group acquired through the process in step S2. Next, the restoration unit 122 solves the created simultaneous equations, to calculate the light intensity of each point light source on the object surface 102 corresponding to the set object distance. The restoration unit 122 then arranges the pixels having the pixel values corresponding to the calculated light intensities, in accordance with the layout of the respective point light sources on the object surface 102. By doing so, the restoration unit 122 generates a restored image in which an image of the object is formed.

In step S4, the imaging unit 41 performs various kinds of processing on the restored image. For example, the restoration unit 122 performs demosaicing, γ correction, white balance adjustment, conversion into a predetermined compression format, and the like, on the restored image as necessary. The restoration unit 122 also supplies the obtained restored image as a sensing image to the front camera ECU 42 via the communication unit 125.

After that, the imaging process comes to an end.

### 2. Second Embodiment

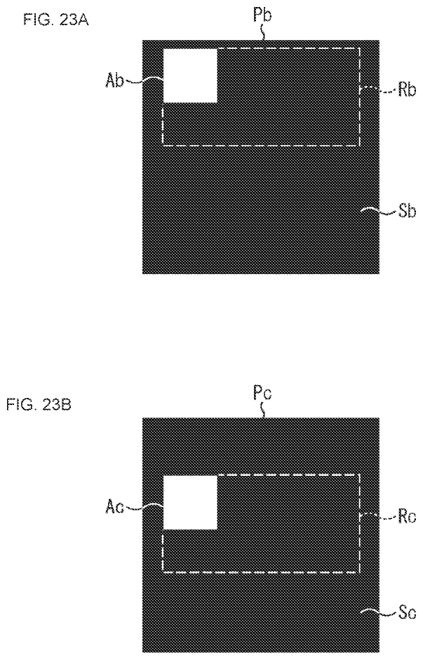

Next, a second embodiment of the present technology is described with reference to FIGS. 22 to 24.

The second embodiment differs from the first embodiment in the light shielding pattern in the pixel array unit of the imaging device 121.

FIG. 22 shows the second embodiment of the light shielding pattern in the pixel array unit of the imaging device 121. FIG. 23 shows an example of the light shielding pattern of a pixel Pb and a pixel Pc that are the second embodiment of the pixels 121a constituting the pixel array unit shown in FIG. 22.

The pixel Pb is disposed in an odd-numbered column in the pixel array unit, and the pixel Pc is disposed in an even-numbered column in the pixel array unit.

The position of the opening setting region is different between the pixel Pb and the pixel Pc. Specifically, the shapes and the sizes of the opening setting region Rb of the light shielding film Sb of the pixel Pb and the opening setting region Rc of the light shielding film Sc of the pixel Pc are the same as those of the opening setting region Ra of the light shielding film Sa of the pixel Pa in FIG. 19.

Meanwhile, the opening setting region Rb is set at a position shifted upward in the pixel Pb, compared with the opening setting region Ra. Also, the opening setting region Rc is set at a position shifted downward in the pixel Pc, compared with the opening setting region Ra. However, the centroid of the opening setting region Rc is biased upward from the center of the pixel Pc, like the centroid of the opening setting region Ra. In this manner, the position in the vertical direction in the pixel is different between the opening setting region Rb and opening setting region Rc.

Further, the opening Ab of the pixel Pb has the same shape and size as those of the opening Aa of the pixel Pa, and is located in the opening setting region Rb according to a rule similar to the rule described above with reference to FIGS. 12 and 13.

Specifically, the opening Ab is located at the left end of the opening setting region Rb in each pixel Pb in the left end column in the pixel array unit, and is located at the upper end of the opening setting region Rb in each pixel Pb in the upper end row in the pixel array unit. Further, as the position of the pixel Pb becomes closer to the right, the opening Ab shifts to the right at equal intervals within the opening setting region Rb, and is located at the right end of the opening setting region Rb in each pixel Pb in the second column from the right in the pixel array unit. Also, as the position of the pixel Pb becomes closer to the bottom, the opening Ab shifts to the bottom at equal intervals within the opening setting region Rb, and is located at the lower end of the opening setting region Rb in each pixel Pb in the lower end row in the pixel array unit.

Accordingly, the position of the opening Ab in the horizontal direction in each pixel Pb is the same among the pixels Pb in the same column in the vertical direction. Also, the position of the opening Ab in the vertical direction in each pixel Pb is the same among the pixels Pb in the same row in the horizontal direction. Accordingly, the position of the opening Ab in each pixel Pb, which is the position at which incident light enters each pixel Pb, varies with each pixel Pb, and, as a result, the incident angle directivities of the respective pixels Pa differ from one another.

Further, the openings Ab of the respective pixels Pb cover the opening setting region Rb. That is, the region in which the openings Ab of the respective pixels Pb are overlapped on one another is equal to the opening setting region Rb. Note that the layout pattern of the openings Ab is not limited to the above configuration, and may be any layout, as long as the region in which the openings Ab are overlapped on one another is equal to the opening setting region Rb. For example, the openings Ab may be randomly arranged within the opening setting region Rb.

Further, the opening Ac of the pixel Pc has the same shape and size as those of the opening Aa of the pixel Pa, and is located in the opening setting region Rc according to a rule similar to the rule described above with reference to FIGS. 12 and 13.

Specifically, the opening Ac is located at the left end of the opening setting region Rc in each pixel Pc in the second column from the left in the pixel array unit, and is located at the upper end of the opening setting region Rc in each pixel Pc in the upper end row in the pixel array unit. Further, as the position of the pixel Pc becomes closer to the right, the opening Ac shifts to the right at equal intervals within the opening setting region Rc, and is located at the right end of the opening setting region Rc in each pixel Pc in the right end column in the pixel array unit. Also, as the position of the pixel Pc becomes closer to the bottom, the opening Ac shifts to the bottom at equal intervals within the opening setting region Rc, and is located at the lower end of the opening setting region Rc in each pixel Pc in the lower end row in the pixel array unit.

Accordingly, the position of the opening Ac in the horizontal direction in each pixel Pc is the same among the pixels Pc in the same column in the vertical direction. Also, the position of the opening Ac in the vertical direction in each pixel Pc is the same among the pixels Pc in the same row in the horizontal direction. Accordingly, the position of the opening Ac in each pixel Pc, which is the position at which incident light enters each pixel Pc, varies with each pixel Pc, and, as a result, the incident angle directivities of the respective pixels Pc differ from one another.

Further, the openings Ac of the respective pixels Pc cover the opening setting region Rc. That is, the region in which the openings Ac of the respective pixels Pc are overlapped on one another is equal to the opening setting region Rc. Note that the layout pattern of the openings Ac is not limited to the above configuration, and may be any layout, as long as the region in which the openings Ac are overlapped on one another is equal to the opening setting region Rc. For example, the openings Ac may be randomly arranged within the opening setting region Rc.

Here, the centroid of the incident angle directivity of each pixel Pb substantially coincides with the centroid of the opening Ab of each pixel Pb, and is biased upward from the center of each pixel Pb. Accordingly, the average of the centroids of the incident angle directivities of the respective pixels Pb is biased upward from the centers of the pixels Pb. That is, the average of the incident angles of centroidal light beams in the respective pixels Pb is biased downward with respect to the normal direction of the light receiving surface of the pixel array unit.

Also, the centroid of the incident angle directivity of each pixel Pc substantially coincides with the centroid of the opening Ac of each pixel Pc, and is biased upward from the center of each pixel Pc among most pixels Pc. Accordingly, the average of the centroids of the incident angle directivities of the respective pixels Pc is biased upward from the centers of the pixels Pc. That is, the average of the incident angles of centroidal light beams in the respective pixels Pc is biased downward with respect to the normal direction of the light receiving surface of the pixel array unit.

Meanwhile, the offset from the center of each pixel Pb in the opening setting region Rb is larger than the offset from the center of each pixel Pc in the opening setting region Rc. Therefore, the average of the incident angles of centroidal light beams in the respective pixels Pb is inclined downward, compared with the average of the incident angles of the centroidal light beams in the respective pixels Pc.

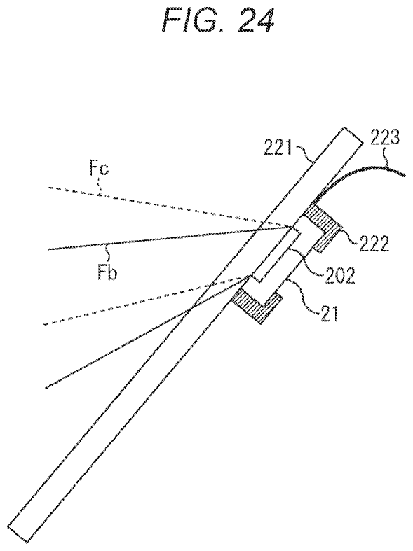

Accordingly, the pixels Pb and the pixels Pc of the imaging device 121 enable imaging of different fields of view in the vertical direction, as shown in FIG. 24. Specifically, the pixels Pb of the imaging device 121 enable imaging of a field of view Fb that extends slightly more downward than the field of view Fa in FIG. 20. Also, the pixels Pc of the imaging device 121 enable imaging of a field of view Fc that extends slightly more upward than the field of view Fa in FIG. 20.

With this arrangement, it is possible to intensively detect lane markings and the like on the road surface in front of and below the vehicle, using a sensing image obtained by the pixels Pb of the imaging device 121, for example. Thus, detection accuracy can be increased. Also, it is possible to intensively detect vehicles, pedestrians, obstacles, and the like in front of the vehicle, using a sensing image obtained by the pixels Pc of the imaging device 121, for example. Thus, detection accuracy can be increased.

Note that a drive unit that independently drives each pixel Pb and each pixel Pc may be provided, for example, and imaging by each pixel Pb and imaging by each pixel Pc may be performed simultaneously or individually.

Further, in a case where imaging by each pixel Pb and imaging by each pixel Pc are simultaneously performed, restoring of a restored image by either side of the pixels may be stopped if the restoring is unnecessary, for example. In a case where only lane markings and the like on the road surface are detected, for example, only a restoration image by the pixels Pb may be restored, and the restoring of a restored image by the pixels Pc may be stopped. Conversely, in a case where only traffic lights, road signs, and the like are detected, for example, only a restoration image by the pixels Pc may be restored, and the restoring of a restored image by the pixels Pb may be stopped. As a result, the processing to be performed by the imaging unit 41 can be reduced.

Further, in a case where imaging by each pixel Pb and imaging by each pixel Pc are individually performed, for example, imaging may be alternately performed, or imaging by one side may be stopped as necessary. In a case where only lane markings and the like on the road surface are detected, for example, only the imaging by the pixels Pb is performed, and the imaging by the pixels Pc may be stopped. As a result, the processing to be performed by the imaging unit 41 can be reduced.

Note that, in this case, coefficient set groups corresponding to the angles of view of restored images in addition to object distances are further prepared, for example, and a restored image is restored with the use the coefficient set group corresponding to the object distance and the angle of view. For example, a coefficient set group for the pixels Pb and a coefficient set group for the pixel Pc are separately prepared, and each coefficient set group is selectively used. Thus, restored images corresponding to the respective pixels can be restored.

### 3. Third Embodiment

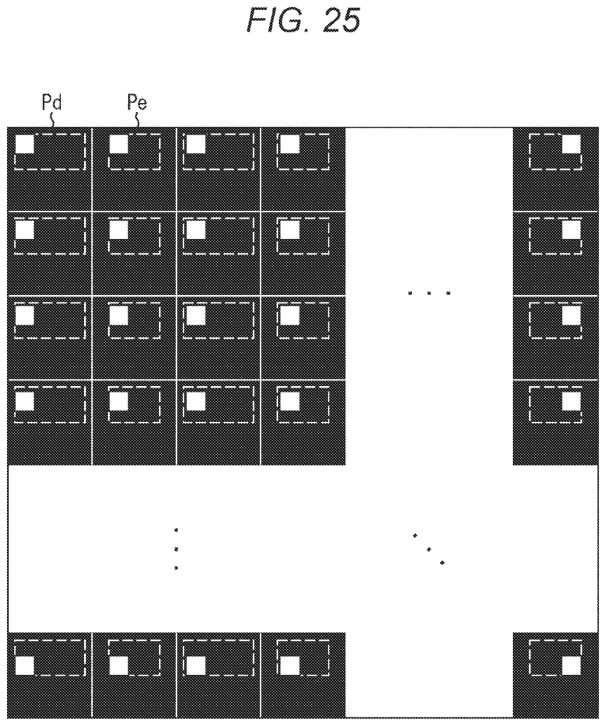

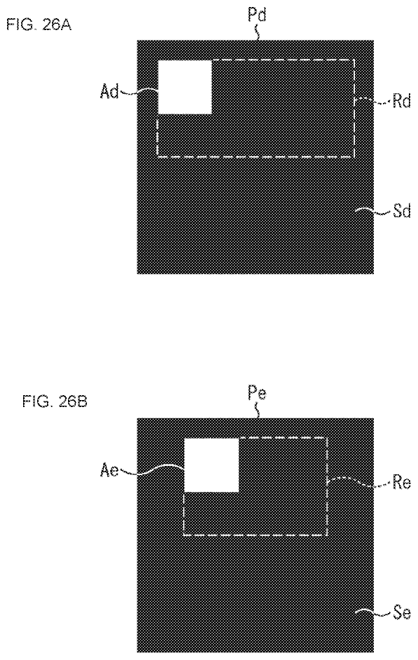

Next, a third embodiment of the present technology is described with reference to FIGS. 25 to 27.

The third embodiment differs from the first embodiment and the second embodiment in the light shielding pattern in the pixel array unit of the imaging device 121.

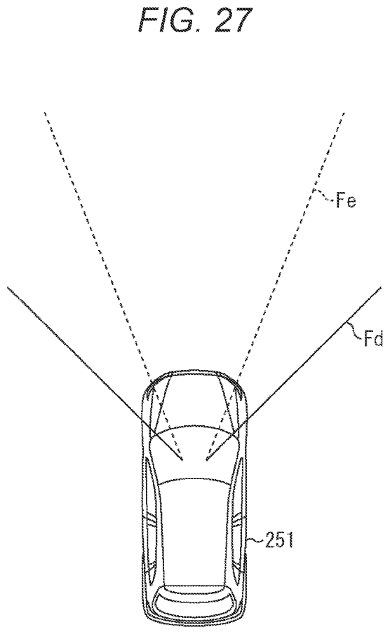

FIG. 25 shows the third embodiment of the light shielding pattern in the pixel array unit of the imaging device 121. FIG. 26 shows an example of the light shielding pattern of a pixel Pd and a pixel Pe that are the third embodiment of the pixels 121a constituting the pixel array unit shown in FIG. 25.

The pixel Pd is disposed in an odd-numbered column in the pixel array unit, and the pixel Pe is disposed in an even-numbered column in the pixel array unit.

The shape and the size of the opening setting region are different between the pixel Pd and the pixel Pe. Specifically, the shape, the size, and the position of the opening setting region Rd of the light shielding film Sd of the pixel Pd are the same as those of the opening setting region Ra of the light shielding film Sa of the pixel Pa in FIG. 19. On the other hand, the opening setting region Re of the light shielding film Se of the pixel Pe has the same height in the vertical direction, but has a smaller width in the horizontal direction, compared with the opening setting region Rd of the light shielding film Sd of the pixel Pd. Meanwhile, the position in the vertical direction is the same between the opening setting region Rd of the pixel Pd and the opening setting region Re of the pixel Pe. Further, the position of the center in the horizontal direction is the same between the opening setting region Rd of the pixel Pd and the opening setting region Re of the pixel Pe.

Furthermore, the opening Ad of the pixel Pd has the same shape and size as those of the opening Aa of the pixel Pa, and is set in the opening setting region Rd according to a rule similar to the rule described above with reference to FIGS. 12 and 13.

Specifically, the opening Ad is located at the left end of the opening setting region Rd in each pixel Pd in the left end column in the pixel array unit, and is located at the upper end of the opening setting region Rd in each pixel Pd in the upper end row in the pixel array unit. Further, as the position of the pixel Pd becomes closer to the right, the opening Ad shifts to the right at equal intervals within the opening setting region Rd, and is located at the right end of the opening setting region Rd in each pixel Pd in the second column from the right in the pixel array unit. Also, as the position of the pixel Pd becomes closer to the bottom, the opening Ad shifts to the bottom at equal intervals within the opening setting region Rd, and is located at the lower end of the opening setting region Rd in each pixel Pd in the lower end row in the pixel array unit.

Accordingly, the position of the opening Ad in the horizontal direction in each pixel Pd is the same among the pixels Pd in the same column in the vertical direction. Also, the position of the opening Ad in the vertical direction in each pixel Pd is the same among the pixels Pd in the same row in the horizontal direction. Accordingly, the position of the opening Ad in each pixel Pd, which is the position at which incident light enters each pixel Pd, varies with each pixel Pd, and, as a result, the incident angle directivities of the respective pixels Pd differ from one another.

Further, the openings Ad of the respective pixels Pd cover the opening setting region Rd. That is, the region in which the openings Ad of the respective pixels Pd are overlapped on one another is equal to the opening setting region Rd. Note that the layout pattern of the openings Ad is not limited to the above configuration, and may be any layout, as long as the region in which the openings Ad are overlapped on one another is equal to the opening setting region Rd. For example, the openings Ad may be randomly arranged within the opening setting region Rd.

Further, the opening Ae of the pixel Pe has the same shape and size as those of the opening Aa of the pixel Pa, and is located in the opening setting region Re according to a rule similar to the rule described above with reference to FIGS. 12 and 13.

Specifically, the opening Ae is located at the left end of the opening setting region Re in each pixel Pe in the second column from the left in the pixel array unit, and is located at the upper end of the opening setting region Re in each pixel Pe in the upper end row in the pixel array unit. Further, as the position of the pixel Pe becomes closer to the right, the opening Ae shifts to the right at equal intervals within the opening setting region Re, and is located at the right end of the opening setting region Re in each pixel Pe in the right end column in the pixel array unit. Also, as the position of the pixel Pe becomes closer to the bottom, the opening Ae shifts to the bottom at equal intervals within the opening setting region Re, and is located at the lower end of the opening setting region Re in each pixel Pe in the lower end row in the pixel array unit.

Accordingly, the position of the opening Ae in the horizontal direction in each pixel Pe is the same among the pixels Pe in the same column in the vertical direction. Also, the position of the opening Ae in the vertical direction in each pixel Pe is the same among the pixels Pe in the same row in the horizontal direction. Accordingly, the position of the opening Ae in each pixel Pe, which is the position at which incident light enters each pixel Pe, varies with each pixel Pe, and, as a result, the incident angle directivities of the respective pixels Pe differ from one another.

Further, the openings Ae of the respective pixels Pe cover the opening setting region Re. That is, the region in which the openings Ab of the respective pixels Pb are overlapped on one another is equal to the opening setting region Re. Note that the layout pattern of the openings Ae is not limited to the above configuration, and may be any layout, as long as the region in which the openings Ae are overlapped on one another is equal to the opening setting region Re. For example, the openings Ae may be randomly arranged within the opening setting region Re.

Here, the average of the centroids of the incident angle directivities of the respective pixels Pd substantially coincides with the average of the centroids of the incident angle directivities of the respective pixels Pa in FIG. 18. Also, the centroid of the incident angle directivity of each pixel Pe substantially coincides with the centroid of the opening Ae of each pixel Pe. Accordingly, the average of the centroids of the incident angle directivities of the respective pixels Pe substantially coincides with the average of the centroids of the incident angle directivities of the respective pixels Pd. As a result, the average of the incident angles of centroidal light beams in the respective pixels Pd and the average of the incident angles of centroidal light beams in the respective pixels Pe substantially coincide with the average of the incident angles of centroidal light beams the respective pixels Pa in FIG. 18.

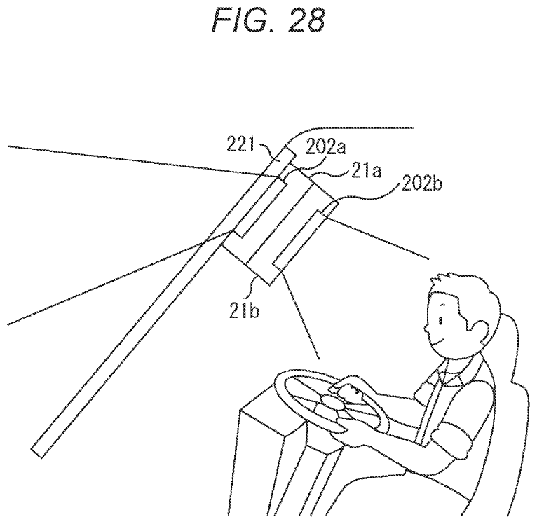

Accordingly, the pixels Pd and the pixels Pe of the imaging device 121 enable imaging of different fields of view in the horizontal direction, as shown in FIG. 27. Specifically, in front of a vehicle 251, the pixels Pd of the imaging device 121 enable imaging of a field of view Fd that is wider than the field of view Fe of the pixels Pe. Accordingly, a wider region in front of the vehicle 251 can be monitored on the basis of a sensing image obtained by the pixels Pd.

Meanwhile, in a case where the number of pixels Pd and the number of pixels Pe are the same, it is possible to obtain a restored image with a higher image quality (a higher object resolution) by restoring an image captured with the use of the pixels Pe having a narrow angle of view than by restoring an image captured with the use of the pixels Pd having a narrow angle of view, as described above. Therefore, it becomes possible to monitor a place farther ahead of the vehicle 251, on the basis of a sensing image obtained by the pixels Pe.

Note that imaging by the respective pixels Pd and imaging by the respective pixels Pe may be performed simultaneously or individually, as in the second embodiment.

Also, a coefficient set group for the pixels Pd and a coefficient set group for the pixel Pe may be separately prepared, and restored images corresponding to the respective pixels may be restored.

### 4. Modifications

The following is a description of modifications of the above described embodiments of the present technology.

<Modifications Relating to Light Shielding Patterns>

Although FIGS. 22 and 25 show examples in which two kinds of opening setting regions are set in the imaging device 121, three or more kinds of opening setting regions may be set.

Also, opening setting regions having different heights may be combined, or opening setting regions having different widths and heights may be combined, for example. Further, not only the position in the vertical direction but also the position in the horizontal direction of the opening setting region may be changed, for example.

Although FIGS. 22 and 25 also show examples in which columns of pixels having different opening setting regions are alternately arranged, rows of pixels having different opening setting regions may be alternately arranged, or pixels having different opening setting regions may be alternately arranged, for example. Further, pixels having different opening setting regions may be randomly arranged, for example, or may be arranged in different regions as in the example shown in the bottom portion of FIG. 11.

Further, FIGS. 18, 22, and 25 show examples in which the position of the opening of each pixel regularly changes as it shifts in the row direction and the column direction. However, the position of the opening may be randomly changed, for example, instead of being regularly changed. Also, the shape and the size of the opening may vary with each pixel, for example. However, it is essential that the openings of the respective pixels cover the opening setting region.

<Modifications Relating to the Front Camera Module 21>

In the examples described above, the imaging unit 41, and the front camera ECU 42 and the MCU 43 are provided on two different semiconductor chips. However, other configurations can be adopted. For example, the imaging device 121 of the imaging unit 41, and the signal processing control unit 111 of the imaging unit 41, the front camera ECU 42, and the MCU 43 may be provided on two different semiconductor chips, or the imaging device 121, the signal processing control unit 111 of the imaging unit 41, and the front camera ECU 42 and the MCU 43 may be provided on three different semiconductor chips. Alternatively, the imaging unit 41, the front camera ECU 42, and the MCU 43 may be provided on one semiconductor chip, for example.

Also, the front camera module 21 may be attached to a window (a side window, a rear window, or the like, for example) of the vehicle other than the windshield 221, to perform imaging in a direction other than the front direction of the vehicle, for example. Further, the direction in which the centroid of the incident angle directivity is biased is not limited to an upward direction with respect to the vertical direction, but may be a downward direction with respect to the horizontal direction or the vertical direction. Particularly, in a case where the camera module 21 is attached to a side window, it is possible to capture a blind spot for the vehicle by decentering the centroid of the incident angle directivity in the horizontal direction.

Further, as shown in FIG. 28, for example, two front camera modules 21a and 21b may be provided in the vehicle so that both the outside and the inside of the vehicle can be imaged.

For example, the front camera module 21a is attached to a position similar to that of the front camera module 21 in FIG. 16, and performs imaging of the outside of the vehicle, image recognition, and the like. On the other hand, the front camera module 21b is attached to the back surface of the front camera module 21a so that the front surface of the LLC chip 202b (or the light receiving surface of the imaging device 121) faces the inside of the vehicle. The front camera module 21b performs imaging of the inside of the vehicle, image recognition, and the like.

The present technology can also be applied in a case where the front camera module 21 is attached in contact with or in proximity to a plate-like transparent or translucent member other than the windows of a vehicle, and imaging in a direction different from the normal direction of the surfaces of the member is performed through the member. For example, the present technology can be applied in a case where imaging in a direction (such as a downward direction, an upward direction, for example) other than the front direction of a window is performed from the inside of a building through the window.

Note that the light shielding pattern in the pixel array unit is set so that the average of the centroids of the incident angle directivities of the respective pixels is biased downward from the center of each pixel in a case where imaging in an upward direction is performed, the average of the centroids of the incident angle directivities of the respective pixels is biased leftward from the center of each pixel in a case where imaging in a rightward direction is performed, and the average of the centroids of the incident angle directivities of the respective pixels is biased rightward from the center of each pixel in a case where imaging in a leftward direction is performed, for example.

<Modifications Relating to the Imaging Device 121>

For example, in each pixel 121a in FIG. 5, a planarizing film may be provided between the color filter 121d and the light shielding film 121b. Also, in each pixel 121a in FIG. 6, for example, a planarizing film may be provided between the color filter 121d and the photodiode 121f.

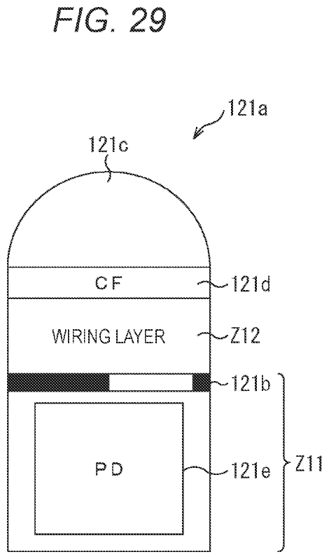

Further, a front-illuminated pixel 121a shown in FIG. 29 can be used in the imaging device 121.

In the pixel 121a shown in FIG. 29, the stacking order of the photoelectric conversion layer Z11 and the wiring layer Z12 is reversed, compared with the pixel 121a shown in FIG. 5. That is, in the pixel 121a shown in FIG. 29, the on-chip lens 121c, the color filter (CF) 121d, the wiring layer Z12, and the photoelectric conversion layer Z11 are stacked in this order from the top. In the photoelectric conversion layer Z11, the light shielding film 121b and the photodiode (PD) 121e are stacked in this order from the top.

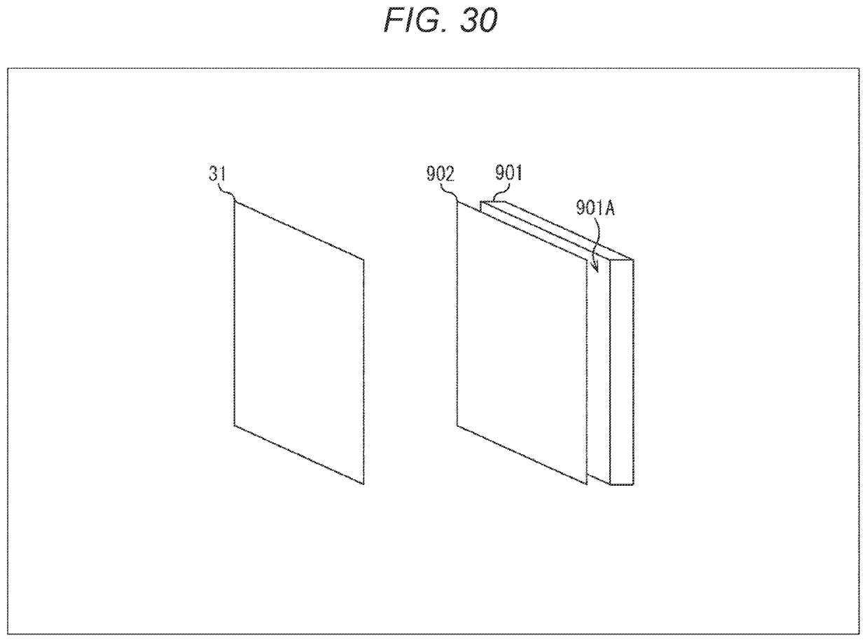

FIG. 5 also shows an example in which the light shielding films 121b are used as modulation elements, or combinations of photodiodes that contribute to outputs are changed, so that different incident angle directivities are provided for the respective pixels. However, according to the present technology, an optical filter 902 covering the light receiving surface of an imaging device 901 may be used as a modulation element so that incident angle directivities are provided for the respective pixels, as shown in FIG. 30, for example.

Specifically, the optical filter 902 is disposed at a predetermined distance from the light receiving surface 901A of the imaging device 901 so as to cover the entire surface of the light receiving surface 901A. Light from the object surface 102 is modulated by the optical filter 902, and then enters the light receiving surface 901A of the imaging device 901.

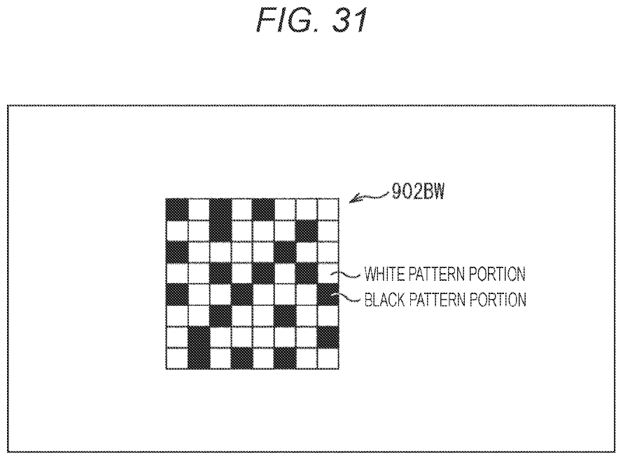

For example, an optical filter 902BW having a black-and-white lattice pattern shown in FIG. 31 can be used as the optical filter 902. In the optical filter 902BW, white pattern portions that transmit light and black pattern portions that block light are randomly arranged. The size of each pattern is set independently of the size of the pixels of the imaging device 901.

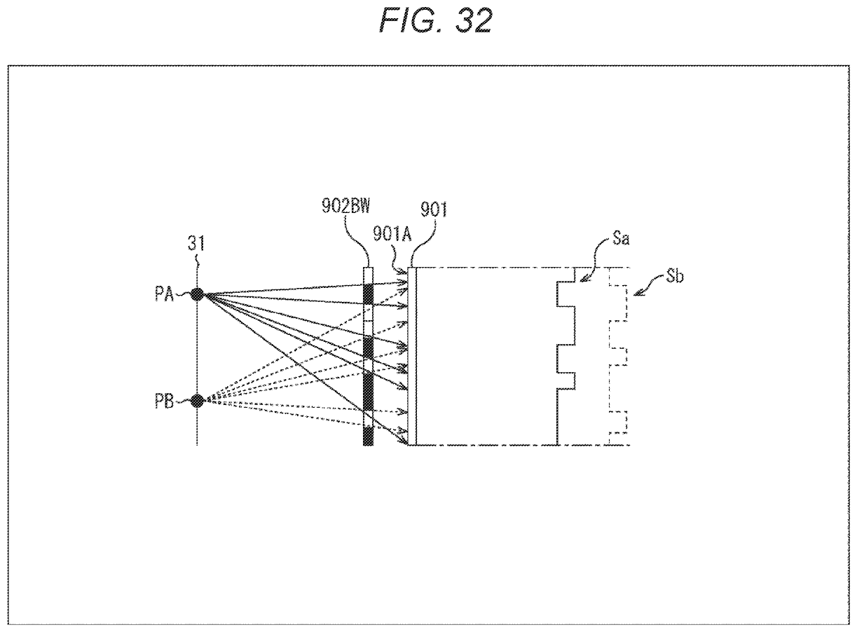

FIG. 32 shows the light-receiving sensitivity characteristics of the imaging device 901 with respect to light from a point light source PA and a point light source PB on the object surface 102 in a case where the optical filter 902BW is used. Light from each of the point light source PA and the point light source PB is modulated by the optical filter 902BW, and then enters the light receiving surface 901A of the imaging device 901.

The light-receiving sensitivity characteristics of the imaging device 901 with respect to light from the point light source PA are like a waveform Sa, for example. That is, shadows are formed by the black pattern portions of the optical filter 902BW, and therefore, a grayscale pattern is formed in the image on the light receiving surface 901A with respect to the light from the point light source PA. Likewise, the light-receiving sensitivity characteristics of the imaging device 901 with respect to light from the point light source PB are like a waveform Sb, for example. That is, shadows are formed by the black pattern portions of the optical filter 902BW, and therefore, a grayscale pattern is formed in the image on the light receiving surface 901A with respect to the light from the point light source PB.

Note that light from the point light source PA and light from the point light source PB have different incident angles with respect to the respective white pattern portions of the optical filter 902BW, and therefore, differences are generated in the appearance of the grayscale pattern on the light receiving surface. Accordingly, each pixel of the imaging device 901 has an incident angle directivity with respect to each point light source on the object surface 102.

Details of this method are disclosed by M. Salman Asif and four others in “Flatcam: Replacing lenses with masks and computation”, “2015 IEEE International Conference on Computer Vision Workshop (ICCVW)”, 2015, pp. 663-666, for example.

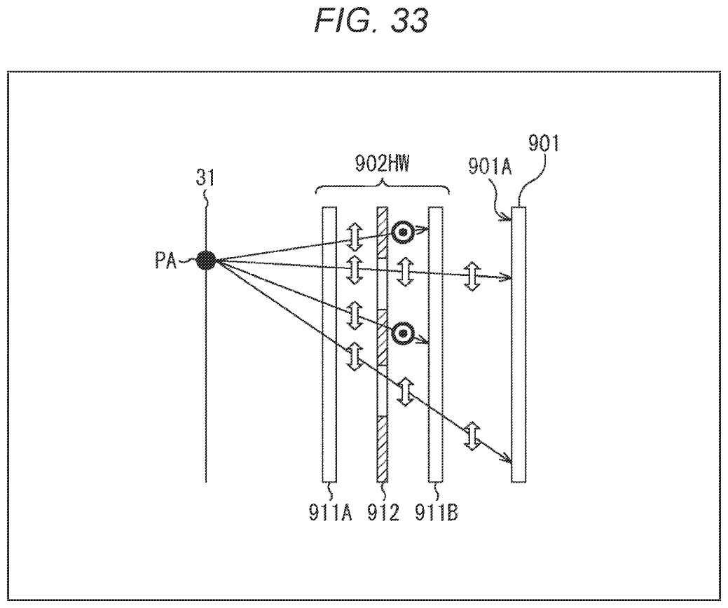

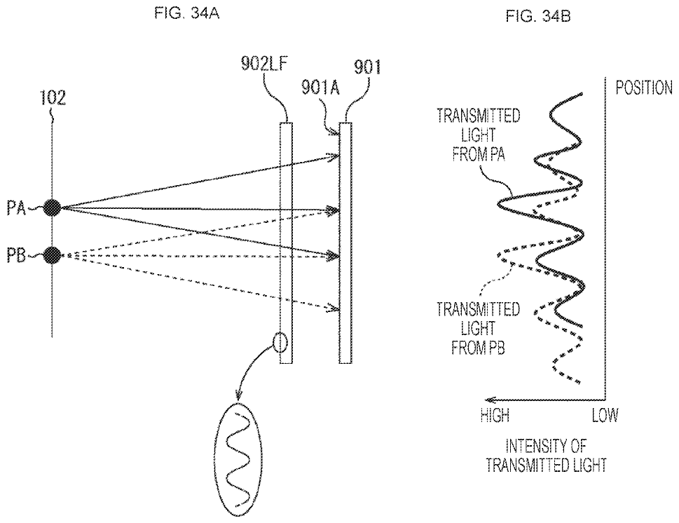

Note that an optical filter 902HW shown in FIG. 33 may be used, instead of the black pattern portions of the optical filter 902BW. The optical filter 902HW includes a linearly polarizing element 911A and a linearly polarizing element 911B that have the same polarizing direction, and a ½ wavelength plate 912. The ½ wavelength plate 912 is interposed between the linearly polarizing element 911A and the linearly polarizing element 911B. Instead of the black pattern portions of the optical filter 902BW, polarizing portions indicated by shaded portions are provided in the ½ wavelength plate 912, and the white pattern portions and the polarizing portions are randomly arranged.

The linearly polarizing element 911A transmits only light in a predetermined polarizing direction among substantially unpolarized light beams emitted from the point light source PA. In the description below, the linearly polarizing element 911A transmits only light in a polarizing direction parallel to the drawing. Of the polarized light beams transmitted through the linearly polarizing element 911A, polarized light transmitted through the polarizing portions of the ½ wavelength plate 912 changes its polarizing direction to a direction perpendicular to the drawing, as the polarization plane is rotated. On the other hand, of the polarized light beams transmitted through the linearly polarizing element 911A, polarized light transmitted through the white pattern portions of the ½ wavelength plate 912 does not change its polarizing direction that remains parallel to the drawing. The linearly polarizing element 911B then transmits the polarized light transmitted through the white pattern portions, but hardly transmits the polarized light transmitted through the polarizing portions. Therefore, the light amount of the polarized light transmitted through the polarizing portions becomes smaller than that of the polarized light transmitted through the white pattern portions. As a result, a grayscale pattern substantially similar to that in the case with the optical filter BW is formed on the light receiving surface 901A of the imaging device 901.

Further, as shown in A of FIG. 34, an optical interference mask can be used as an optical filter 902LF. Light emitted from the point light sources PA and PB on the object surface 102 is emitted onto the light receiving surface 901A of the imaging device 901 via the optical filter 902LF. As shown in an enlarged view in a lower portion of A of FIG. 34, the light incident face of the optical filter 902LF has irregularities of a size similar to the size of a wavelength, for example. Also, the optical filter 902LF maximizes transmission of light of a specific wavelength emitted from the vertical direction. When the change in the incident angle of light of the specific wavelength emitted from the point light sources PA and PB on the object surface 102 with respect to the optical filter 902LF (or the inclination with respect to the vertical direction) becomes greater, the optical path length changes. Here, when the optical path length is an odd multiple of the half wavelength, light beams weaken each other. When the optical path length is an even multiple of the half wavelength, light beams strengthen each other. That is, as shown in B of FIG. 34, the intensity of transmitted light of the specific wavelength emitted from the point light sources PA and PB and transmitted through the optical filter 902LF is modulated in accordance with the incident angle with respect to the optical filter 902LF, and then enters the light receiving surface 901A of the imaging device 901. Accordingly, the detection signal output from each pixel of the imaging device 901 is a signal obtained by combining the light intensities after modulation of the respective point light sources for each pixel.

Details of this method are disclosed in JP 2016-510910 W mentioned above, for example.

### Other Modifications

The present technology can also be applied to an imaging apparatus and an imaging device that images light of a wavelength other than visible light, such as infrared light. In this case, a restored image is not an image from which the user can visually recognize the object, but an image from which the user cannot visually recognize the object. In this case, the present technology is also used to increase the quality of a restored image in an image processing apparatus or the like that can recognize the object. Note that it is difficult for a conventional imaging lens to transmit far-infrared light, and therefore, the present technology is effective in a case where imaging of far-infrared light is performed, for example. Accordingly, a restored image may be an image of far-infrared light. Alternatively, a restored image is not necessarily an image of far-infrared light, but may be an image of some other visible light or invisible light.

Further, by applying machine learning such as deep learning, for example, it is also possible to perform image recognition and the like using a detection image before restoration, without a restored image. In this case, the present technology can also be used to increase the accuracy of image recognition using a detection image before restoration. In other words, the image quality of the detection image before restoration becomes higher.

In this case, the front camera ECU 42 in FIG. 1 performs image recognition using the detection image, for example.

### 5. Other Aspects

The series of processes described above can be performed by hardware, and can also be performed by software. In a case where the series of processes are to be performed by software, the program that forms the software is installed into a computer. Here, the computer may be a computer (such as the control unit 123, for example) incorporated in dedicated hardware.

The program to be executed by the computer may be recorded on a recording medium as a packaged medium or the like, for example, and be then provided. Alternatively, the program can be provided via a wired or wireless transmission medium, such as a local area network, the Internet, or digital satellite broadcasting.

Note that the program to be executed by the computer may be a program for performing processes in chronological order in accordance with the sequence described in this specification, or may be a program for performing processes in parallel or performing a process when necessary, such as when there is a call.

Further, embodiments of the present technology are not limited to the above described embodiments, and various modifications may be made to them without departing from the scope of the present technology.

For example, the present technology may be embodied in a cloud computing configuration in which one function is shared among a plurality of devices via a network, and processing is performed by the devices cooperating with one another.

Further, the respective steps described with reference to the flowcharts described above may be carried out by one device or may be shared among a plurality of devices.

Furthermore, in a case where a plurality of processes is included in one step, the plurality of processes included in the one step may be performed by one device or may be shared among a plurality of devices.

Note that the present technology may also be embodied in the configurations described below.

(1)

An imaging system including

an imaging device that includes a plurality of pixels that receives incident light entering from an object after passing through neither an imaging lens nor a pinhole, and each outputs one detection signal indicating an output pixel value modulated in accordance with an incident angle of the incident light, the imaging device being mounted so that a light receiving surface faces a surface of a windshield on an inner side of a vehicle and is in contact with or in proximity to the surface of the windshield,

in which an average of centroids of incident angle directivities indicating directivities of the plurality of pixels with respect to the incident angle of the incident light is biased in one direction from a center of the pixel.

(2)

The imaging system according to (1), in which

the plurality of pixels includes a plurality of first pixels in which the incident light enters at different positions from one another in a first region in which the centroid is biased in one direction from the center of the pixel.

(3)

The imaging system according to (2), in which

each of the plurality of pixels includes:

a photoelectric conversion element; and

a light shielding film that blocks part of the incident light from entering the photoelectric conversion element, and

openings of the light shielding films of the plurality of first pixels are located at different positions from one another in the first region.

(4).

The imaging system according to (3), in which

the plurality of pixels further includes a plurality of second pixels in which centroids are biased in one direction from the center of the pixel, and openings of the light shielding films are located at different positions from one another in a second region different from the first region.

(5)

The imaging system according to (4), in which

a position in a vertical direction in the pixel is different between the first region and the second region.

(6)

The imaging system according to (5), in which

the first region and the second region have the same shape and size.

(7)

The imaging system according to any one of (4) to (6), in which

the first region and the second region have different widths in a horizontal direction.

(8)

The imaging system according to any one of (4) to (7), further including

a drive unit that drives the plurality of first pixels and the plurality of second pixels independently of each other.

(9)

The imaging system according to any one of (1) to (8), further including

a first signal processing unit that processes a detection image generated on the basis of the detection signals of the plurality of pixels.

(10)

The imaging system according to (9), in which

the first signal processing unit restores a restored image from the detection image.

(11)

The imaging system according to (10), further including

a second signal processing unit that performs image recognition on a view in front of the vehicle, on the basis of the restored image.

(12)

The imaging system according to (11), further including:

a first semiconductor chip that includes the imaging device;

a second semiconductor chip that includes the second signal processing unit; and

a substrate on which the first semiconductor chip and the second semiconductor chip are mounted.

(13)

The imaging system according to (9), in which

the first signal processing unit performs image recognition on a view in front of the vehicle, on the basis of the detection image.

(14)

The imaging system according to (13), further including:

a first semiconductor chip that includes the imaging device;

a second semiconductor chip that includes the first signal processing unit; and

a substrate on which the first semiconductor chip and the second semiconductor chip are mounted.

(15)

The imaging system according to (1), in which

the average of the centroids of the incident angle directivities of the plurality of pixels is biased in one direction from the center of the pixel, in accordance with an inclination of the windshield.

(16)

The imaging system according to (1), in which

the centroid of the incident angle directivity of each of the plurality of pixels is biased in one direction from the center of the pixel.

(17)

The imaging system according to any one of (1) to (16), in which

the average of the centroids of the incident angle directivities is biased upward with respect to a vertical direction in a state where the imaging device is attached to the vehicle.

(18)

The imaging system according to any one of (1) to (17), in which

the imaging device is detachably attached to the windshield via a bracket.

(19)

An imaging device including

a plurality of pixels that receives incident light entering from an object after passing through neither an imaging lens nor a pinhole, and each outputs a detection signal indicating an output pixel value modulated in accordance with an incident angle of the incident light,

in which an average of centroids of incident angle directivities indicating directivities of the plurality of pixels with respect to the incident angle of the incident light deviates from a center of the pixel.

(20)

The imaging device according to (19), in which

the imaging device is mounted so that a light receiving surface faces a surface of a windshield on an inner side of a vehicle and is in contact with or in proximity to the surface of the windshield, and

the average of the centroids of the incident angle directivities of the plurality of pixels with respect to the incident light is biased upward from the center of the pixel.

Note that the advantageous effects described in this specification are merely examples, and the advantageous effects of the present technology are not limited to them and may include other effects.

### REFERENCE SIGNS LIST

11 In-vehicle system
21 Front camera module
41 Imaging unit
42 Front camera ECU
43 MCU
111 Signal processing control unit
121 Imaging device
122 Restoration unit
123 Control unit
201 Substrate
202 LLC chip
203 Signal processing chip
221 Windshield
Pa to Pe Pixel
Aa to Ae Opening
Ra to Re Opening setting region
Sa to Se Light shielding film

1. An imaging system comprising
an imaging device that includes a plurality of pixels that receives incident light entering from an object after passing through neither an imaging lens nor a pinhole, and each outputs a detection signal indicating an output pixel value modulated in accordance with an incident angle of the incident light, the imaging device being mounted so that a light receiving surface faces a surface of a windshield on an inner side of a vehicle and is in contact with or in proximity to the surface of the windshield,
wherein an average of centroids of incident angle directivities indicating directivities of the plurality of pixels with respect to the incident angle of the incident light is biased in one direction from a center of the pixel.

2. The imaging system according to claim 1, wherein
the plurality of pixels includes a plurality of first pixels in which the incident light enters at different positions from one another in a first region in which the centroid is biased in one direction from the center of the pixel.

3. The imaging system according to claim 2, wherein
each of the plurality of pixels includes:
a photoelectric conversion element; and
a light shielding film that blocks part of the incident light from entering the photoelectric conversion element, and
openings of the light shielding films of the plurality of first pixels are located at different positions from one another in the first region.

4. The imaging system according to claim 3, wherein
the plurality of pixels further includes a plurality of second pixels in which centroids are biased in one direction from the center of the pixel, and openings of the light shielding films are located at different positions from one another in a second region different from the first region.

5. The imaging system according to claim 4, wherein
a position in a vertical direction in the pixel is different between the first region and the second region.

6. The imaging system according to claim 5, wherein
the first region and the second region have the same shape and size.

7. The imaging system according to claim 4, wherein
the first region and the second region have different widths in a horizontal direction.

8. The imaging system according to claim 4, further comprising
a drive unit that drives the plurality of first pixels and the plurality of second pixels independently of each other.

9. The imaging system according to claim 1, further comprising
a first signal processing unit that processes a detection image generated on a basis of the detection signals of the plurality of pixels.

10. The imaging system according to claim 9, wherein
the first signal processing unit restores a restored image from the detection image.

11. The imaging system according to claim 10, further comprising
a second signal processing unit that performs image recognition on a view in front of the vehicle, on a basis of the restored image.

12. The imaging system according to claim 11, further comprising:
a first semiconductor chip that includes the imaging device;
a second semiconductor chip that includes the second signal processing unit; and
a substrate on which the first semiconductor chip and the second semiconductor chip are mounted.

13. The imaging system according to claim 9, wherein
the first signal processing unit performs image recognition on a view in front of the vehicle, on a basis of the detection image.

14. The imaging system according to claim 13, further comprising:
a first semiconductor chip that includes the imaging device;
a second semiconductor chip that includes the first signal processing unit; and
a substrate on which the first semiconductor chip and the second semiconductor chip are mounted.

15. The imaging system according to claim 1, wherein
the average of the centroids of the incident angle directivities of the plurality of pixels is biased in one direction from the center of the pixel, in accordance with an inclination of the windshield.

16. The imaging system according to claim 1, wherein
the centroid of the incident angle directivity of each of the plurality of pixels is biased in one direction from the center of the pixel.

17. The imaging system according to claim 1, wherein
the average of the centroids of the incident angle directivities is biased upward with respect to a vertical direction in a state where the imaging device is attached to the vehicle.

18. The imaging system according to claim 1, wherein
the imaging device is detachably attached to the windshield via a bracket.

19. An imaging device comprising
a plurality of pixels that receives incident light entering from an object after passing through neither an imaging lens nor a pinhole, and each outputs a detection signal indicating an output pixel value modulated in accordance with an incident angle of the incident light,
wherein an average of centroids of incident angle directivities indicating directivities of the plurality of pixels with respect to the incident angle of the incident light deviates from a center of the pixel.

20. The imaging device according to claim 19, wherein
the imaging device is mounted so that a light receiving surface faces a surface of a windshield on an inner side of a vehicle and is in contact with or in proximity to the surface of the windshield, and
the average of the centroids of the incident angle directivities of the plurality of pixels with respect to the incident light is biased upward from the center of the pixel.
